(19) United States
(12) Patent Application Publication
(10) Pub. No.: US 2024/0365574 A1
(43) Pub. Date: Oct. 31, 2024

(54) IMAGING ELEMENT AND IMAGING DEVICE

(71) Applicants: SONY SEMICONDUCTOR SOLUTIONS CORPORATION, KANAGAWA (JP); SONY GROUP CORPORATION, TOKYO (JP)

(72) Inventors: YOSUKE SAITO, KANAGAWA (JP); MASATO KANNO, TOKYO (JP); SHINNOSUKE HATTORI, TOKYO (JP); HAJIME KOBAYASHI, TOKYO (JP); TAKEO TSUKAMOTO, TOKYO (JP); YUSHIRO NAKAGOME, KANAGAWA (JP); CHIAKI TAKAHASHI, TOKYO (JP); MIKA INABA, KANAGAWA (JP); YOSUKE SUDA, KANAGAWA (JP); KEI FUKUHARA, KANAGAWA (JP); HIDEAKI MOGI, KANAGAWA (JP)

(21) Appl. No.: 18/290,934

(22) PCT Filed: Mar. 16, 2022
(86) PCT No.: PCT/JP2022/011843

§ 371 Date: Jan. 22, 2024

(30) Foreign Application Priority Data
Jul. 28, 2021 (JP) 2021-123630

(51) Int. Cl. H10K 39/00; H01L 25/16; H01L 27/146; H10K 30/30; H10K 39/32

(52) U.S. Cl. CPC H10K 39/601; H01L 25/167; H01L 27/14645; H10K 30/30; H10K 39/32

(57) ABSTRACT

An imaging element according to an embodiment of the present disclosure includes: a first electrode; a second electrode disposed to be opposed to the first electrode; an organic layer provided between the first electrode and the second electrode and at least including a photoelectric conversion layer; and a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 eV or an electron affinity greater than a work function of the second electrode, the second carbon-containing compound having an ionization potential greater than 5.5 eV.

### TECHNICAL FIELD

The present disclosure relates to an imaging element using an organic material, for example, and an imaging device including the imaging element.

### BACKGROUND ART

In recent years, there has been proposed a so-called vertical spectroscopic imaging element having a vertical multilayer structure in which an organic photoelectric conversion section is disposed above a semiconductor substrate. In the vertical spectroscopic imaging element, light beams in red and blue wavelength ranges are photoelectrically converted by respective photoelectric conversion sections (photodiodes PD1 and PD2) formed in a semiconductor substrate, and light in a green wavelength range is photoelectrically converted by an organic photoelectric conversion film provided in an organic photoelectric conversion section.

In such an imaging element, electric charge generated through photoelectric conversion by the photodiodes PD1 and PD2 is temporarily accumulated in the photodiodes PD1 and PD2, and then transferred to respective floating diffusion layers. This makes it possible to fully deplete the photodiodes PD1 and PD2. Meanwhile, the electric charge generated by the organic photoelectric conversion section is directly accumulated in a floating diffusion layer. This makes it difficult to fully deplete the organic photoelectric conversion section, thus increasing kTC noise and degenerating random noise. This leads to lower image quality in imaging.

In contrast, for example, PTL 1 discloses an imaging element provided with an electrode for electric charge accumulation in a photoelectric conversion section that is provided on a semiconductor substrate and includes a first electrode, a photoelectric conversion layer, and a second electrode which are stacked, thereby suppressing a decrease in image quality in imaging. The electrode for electric charge accumulation is disposed to be spaced apart from the first electrode and opposed to the photoelectric conversion layer with an insulating layer interposed therebetween.

### CITATION LIST

### Patent Literature

PTL 1: Japanese Unexamined Patent Application Publication No. 2017-157816

### SUMMARY OF THE INVENTION

Incidentally, an imaging element is required to have improved manufacturing yield and improved element characteristics.

It is desirable to provide an imaging element and an imaging device that make it possible to improve manufacturing yield and element characteristics.

An imaging element according to an embodiment of the present disclosure includes: a first electrode; a second electrode disposed to be opposed to the first electrode; an organic layer provided between the first electrode and the second electrode and at least including a photoelectric conversion layer; and a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 e V or an electron affinity greater than a work function of the second electrode, the second carbon-containing compound having an ionization potential greater than 5.5 eV.

An imaging device according to an embodiment of the present disclosure includes, for each of a plurality of pixels, one or a plurality of the imaging elements according to an embodiment of the present disclosure.

In the imaging element according to an embodiment of the present disclosure and the imaging device according to an embodiment of the present disclosure, the first semiconductor layer is provided between the organic layer at least including the photoelectric conversion layer and the second electrode. The first semiconductor layer has an electron affinity of 4.5 eV or more and 6.0 eV or less, and includes the first carbon-containing compound and the second carbon-containing compound. The first carbon-containing compound has an electron affinity greater than 4.8 eV or an electron affinity greater than a work function of the second electrode. The second carbon-containing compound has an ionization potential greater than 5.5 eV. This improves adhesiveness between the organic layer and the second electrode, and enhances an electric field to be substantially applied to the photoelectric conversion layer.

### BRIEF DESCRIPTION OF THE DRAWINGS

FIG. 1 is a schematic cross-sectional view of an example of an outline configuration of an imaging element according to a first embodiment of the present disclosure.

FIG. 2 is a schematic plan view of an example of a pixel configuration of the imaging element illustrated in FIG. 1.

FIG. 3 is an equivalent circuit diagram of the imaging element illustrated in FIG. 1.

FIG. 4 is a schematic view of an arrangement of transistors constituting a controller and a lower electrode of an organic photoelectric conversion section illustrated in FIG. 1.

FIG. 5A illustrates an energy level of a monolayer film of a candidate material of a work function adjustment layer.

FIG. 5B is a diagram illustrating a change in an energy level of a work function adjustment layer when a mixed film with the candidate material illustrated in FIG. 5B is adopted.

FIG. 6 is an explanatory cross-sectional view of a method of manufacturing the imaging element illustrated in FIG. 1.

FIG. 7 is a cross-sectional view of a step subsequent to FIG. 6.

FIG. 8 is a cross-sectional view of a step subsequent to FIG. 7.

FIG. 9 is a cross-sectional view of a step subsequent to FIG. 8.

FIG. 10 is a cross-sectional view of a step subsequent to FIG. 9.

FIG. 11 is a cross-sectional view of a step subsequent to FIG. 10.

FIG. 12 is a cross-sectional view of a step subsequent to FIG. 11.

FIG. 13 is a timing diagram illustrating an operation example of the imaging element illustrated in FIG. 1.

FIG. 14 is a schematic cross-sectional view of an example of an outline configuration of an imaging element according to a second embodiment of the present disclosure.

FIG. 15 is a schematic cross-sectional view of an example of a configuration of an imaging element according to Modification Example 1 of the present disclosure.

FIG. 16A is a schematic cross-sectional view of an example of a configuration of an imaging element according to Modification Example 2 of the present disclosure.

FIG. 16B is a schematic view of a planar configuration of the imaging element illustrated in FIG. 16A.

FIG. 17A is a schematic cross-sectional view of an example of a configuration of an imaging element according to Modification Example 3 of the present disclosure.

FIG. 17B is a schematic view of a planar configuration of the imaging element illustrated in FIG. 17A.

FIG. 18 is a schematic cross-sectional view of an example of a configuration of an imaging element according to Modification Example 4 of the present disclosure.

FIG. 19 is a schematic cross-sectional view of another example of the configuration of the imaging element according to Modification Example 4 of the present disclosure.

FIG. 20A is a schematic cross-sectional view of another example of the configuration of the imaging element according to Modification Example 4 of the present disclosure.

FIG. 20B is a schematic view of a planar configuration of the imaging element illustrated in FIG. 20A.

FIG. 21A is a schematic cross-sectional view of another example of the configuration of the imaging element according to Modification Example 4 of the present disclosure.

FIG. 21B is a schematic view of a planar configuration of the imaging element illustrated in FIG. 21A.

FIG. 22 is a block diagram illustrating a configuration of an imaging device using the imaging element illustrated in FIG. 1 as a pixel.

FIG. 23 is a function block diagram illustrating an example of an electronic apparatus (camera) using the imaging device illustrated in FIG. 22.

FIG. 24A is a schematic view of an example of an overall configuration of a photodetection system using the imaging device illustrated in FIG. 22.

FIG. 24B is a diagram illustrating an example of a circuit configuration of the photodetection system illustrated in FIG. 24A.

FIG. 25 is a view depicting an example of a schematic configuration of an endoscopic surgery system.

FIG. 26 is a block diagram depicting an example of a functional configuration of a camera head and a camera control unit (CCU).

FIG. 27 is a block diagram depicting an example of schematic configuration of a vehicle control system.

FIG. 28 is a diagram of assistance in explaining an example of installation positions of an outside-vehicle information detecting section and an imaging section.

FIG. 29 is a schematic cross-sectional view of a device structure as Evaluation Sample 1.

FIG. 30 is a schematic cross-sectional view of a device structure as Evaluation Sample 2.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment (An example of providing a work function adjustment layer including two types of materials between a photoelectric conversion layer and an upper electrode)
   1-1. Configuring of Imaging Element
   1-2. Method of Manufacturing Imaging Element
   1-3. Workings and Effects
2. Second Embodiment (An example of providing an electron injection promoting layer having a predetermined energy level between a work function adjustment layer and an upper electrode)
3. Modification Examples
   3-1. Modification Example 1 (Another example of the configuration of the imaging element)
   3-2. Modification Example 2 (Another example of the configuration of the imaging element)
   3-3. Modification Example 3 (Another example of the configuration of the imaging element)
   3-4. Modification Example 4 (Another example of the configuration of the imaging element)
4. Application example
5. Practical Application Examples
6. Examples

### 1. First Embodiment

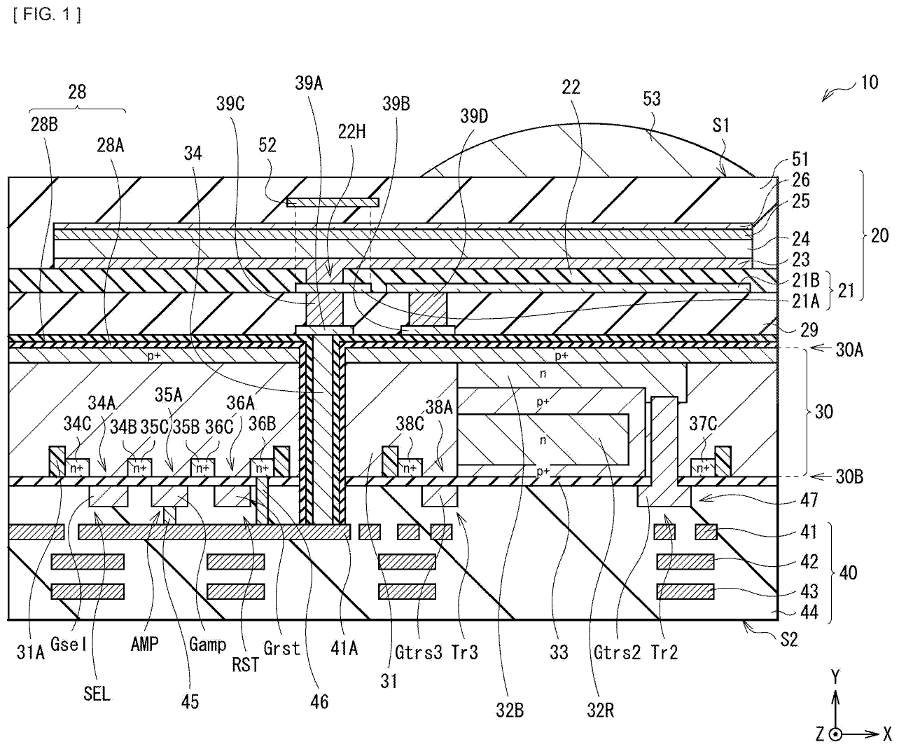

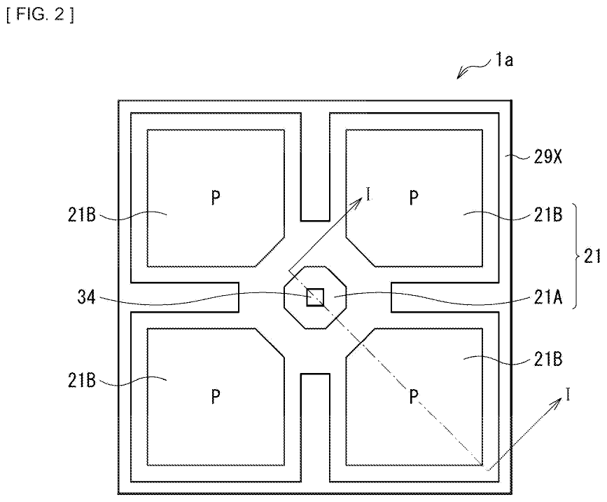

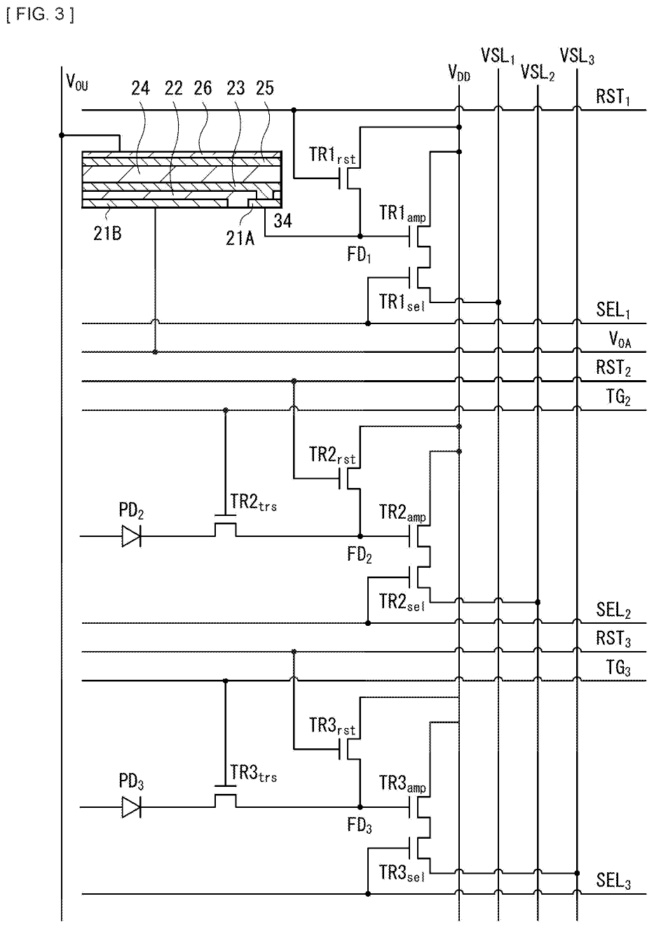

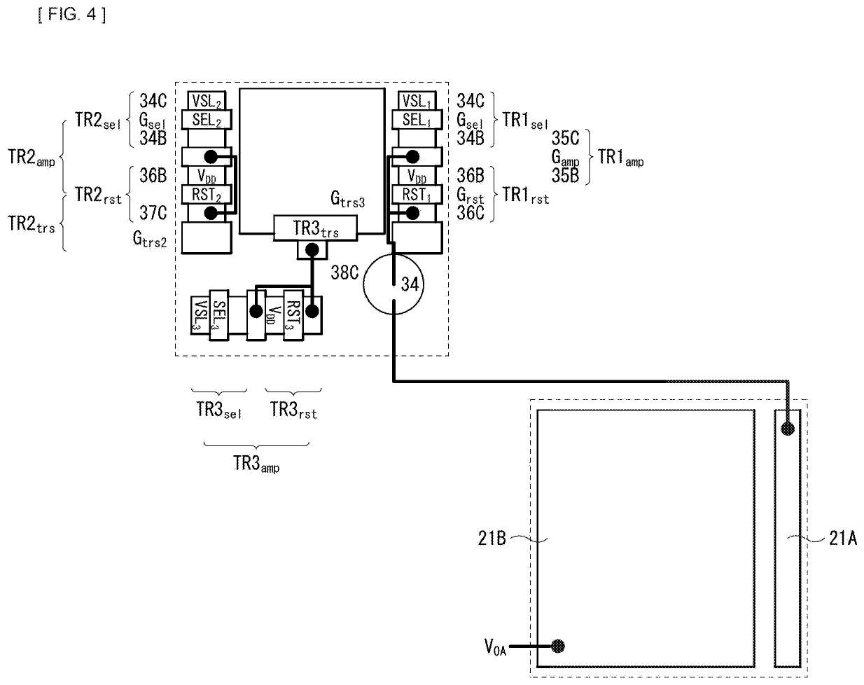

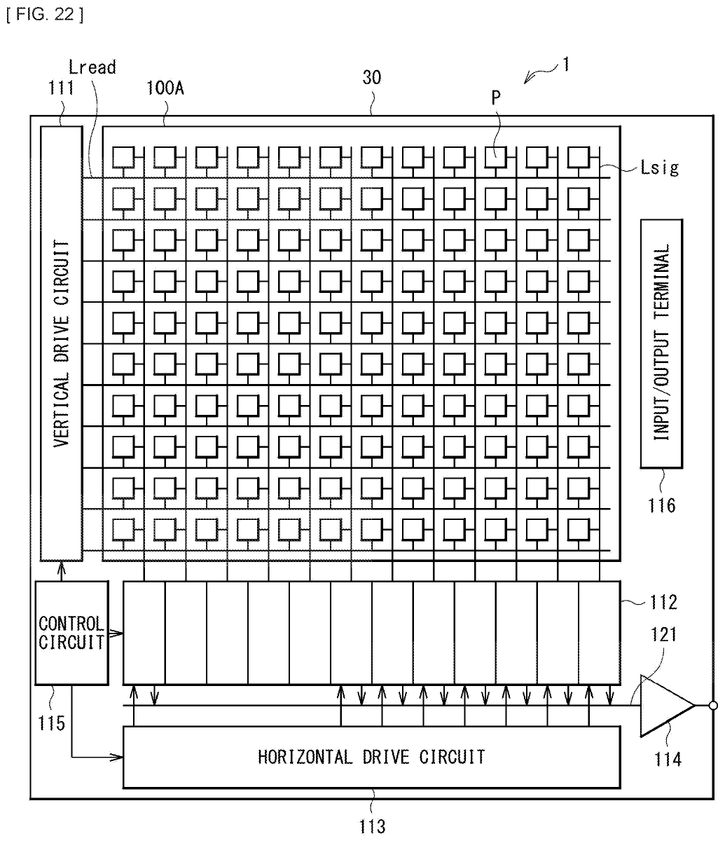

FIG. 1 illustrates a cross-sectional configuration of an imaging element (an imaging element 10) according to a first embodiment of the present disclosure. FIG. 2 schematically illustrates an example of a planar configuration of the imaging element 10 illustrated in FIG. 1, and FIG. 1 illustrates a cross-section along a line I-I illustrated in FIG. 2. FIG. 3 is an equivalent circuit diagram of the imaging element 10 illustrated in FIG. 1. FIG. 4 schematically illustrates an arrangement of a lower electrode 21 and transistors constituting a controller of the imaging element 10 illustrated in FIG. 1. The imaging element 10 constitutes, for example, one pixel (a unit pixel P) in an imaging device (an imaging device 1; see FIG. 22) such as a CMOS (Complementary Metal Oxide Semiconductor) image sensor used for an electronic apparatus such as a digital still camera or a video camera. The imaging element 10 according to the present embodiment is provided with a work function adjustment layer 25 having an electron affinity of 4.5 eV or more and 6.0 eV or less between a photoelectric conversion layer 24 and an upper electrode 26 in an organic photoelectric conversion section 20 provided above a semiconductor substrate 30. The work function adjustment layer 25 is configured using two types of materials having a predetermined electron affinity and ionization potential.

### (1-1. Configuration of Imaging Element)

The imaging element 10 is a so-called vertical spectroscopic imaging element in which the one organic photoelectric conversion section 20 and two inorganic photoelectric conversion sections 32B and 32R are stacked in a vertical direction. The organic photoelectric conversion section 20 is provided on a side of a first surface (back surface) 30A of the semiconductor substrate 30. The inorganic photoelectric conversion sections 32B and 32R are formed to be embedded in the semiconductor substrate 30, and are stacked in a thickness direction of the semiconductor substrate 30. The organic photoelectric conversion section 20 includes the photoelectric conversion layer 24 between the lower electrode 21 and the upper electrode 26 that are disposed to be opposed to each other. The photoelectric conversion layer 24 is formed by using an organic material. The photoelectric conversion layer 24 includes a p-type semiconductor and an n-type semiconductor, and has a bulk hetero junction structure in the layer. The bulk hetero junction structure is a p/n junction surface formed by mixing a p-type semiconductor and an n-type semiconductor.

The organic photoelectric conversion section 20 and the inorganic photoelectric conversion sections 32B and 32R perform photoelectric conversion by selectively detecting respective light beams in different wavelength ranges. Specifically, the organic photoelectric conversion section 20 acquires, for example, a color signal of green (G). The inorganic photoelectric conversion sections 32B and 32R respectively acquire, for example, a color signal of blue (B) and a color signal of red (R) by using a difference between absorption coefficients. This enables the imaging element 10 to acquire a plurality of types of color signals in one pixel without using any color filter.

It is to be noted that, in the present embodiment, a case is described where electrons of excitons (electron-hole pairs) generated through photoelectric conversion are read as signal charge. In other words, a case is described where the n-type semiconductor region is used as a photoelectric conversion layer. In addition, in the drawings, “+ (plus)” attached to “p” and “n” indicates a higher p-type or n-type impurity concentration.

A second surface (front surface) 30B of the semiconductor substrate 30 is provided, for example, with floating diffusions FD1 (a region 36B in the semiconductor substrate 30), FD2 (a region 37C in the semiconductor substrate 30), and FD3 (a region 38C in the semiconductor substrate 30), transfer transistors Tr2 and Tr3, an amplifier transistor (modulation element) AMP, a reset transistor RST, a selection transistor SEL, and a multilayer wiring layer 40. The multilayer wiring layer 40 has, for example, a configuration in which wiring layers 41, 42, and 43 are stacked in an insulating layer 44.

It is to be noted that, in the diagram, a light incident side S1 denotes a side of the first surface 30A of the semiconductor substrate 30, and a wiring layer side S2 denotes a side of the second surface 30B.

The organic photoelectric conversion section 20 has a configuration in which the lower electrode 21, a charge accumulation layer 23, the photoelectric conversion layer 24, the work function adjustment layer 25, and the upper electrode 26 are stacked in this order from the side of the first surface 30A of the semiconductor substrate 30. In addition, there is provided an insulating layer 22 between the lower electrode 21 and the charge accumulation layer 23. For example, the lower electrodes 21 are formed separately for the respective imaging elements 10. Although described below in detail, the lower electrodes 21 each include a readout electrode 21A and an accumulation electrode 21B that are separated from each other with the insulating layer 22 interposed therebetween. The readout electrode 21A of the lower electrode 21 is electrically coupled to the charge accumulation layer 23 through an opening 22H provided in the insulating layer 22. FIG. 1 illustrates an example in which the charge accumulation layers 23, the photoelectric conversion layers 24, the work function adjustment layers 25, and the upper electrodes 26 are separately formed for the respective imaging elements 10. For example, the charge accumulation layer 23, the photoelectric conversion layer 24, the work function adjustment layer 25, and the upper electrode 26 may be, however, formed as continuous layers common to the plurality of imaging elements 10.

For example, there are provided an insulating layer 28 and an interlayer insulating layer 29 between the first surface 30A of the semiconductor substrate 30 and the lower electrode 21. The insulating layer 28 includes a layer (fixed charge layer) 28A having fixed electric charge and a dielectric layer 28B having an insulation property. There is provided a protective layer 51 on the upper electrode 26. There is provided a light-blocking film 52, for example, above the readout electrode 21A in the protective layer 51. It is sufficient for this light-blocking film 52 to be provided to cover at least a region of the readout electrode 21A in direct contact with the photoelectric conversion layer 24 without overlapping at least the accumulation electrode 21B. There are provided optical members such as a planarization layer (unillustrated) and an on-chip lens 53 above the protective layer 51.

There is provided a through-electrode 34 between the first surface 30A and the second surface 30B of the semiconductor substrate 30. The organic photoelectric conversion section 20 is coupled, via the through-electrode 34, to a gate Gamp of the amplifier transistor AMP provided on the side of the second surface 30B of the semiconductor substrate 30 and to one source/drain region 36B of the reset transistor RST (a reset transistor Tr1rst) also serving as the floating diffusion FD1. This enables the imaging element 10 to favorably transfer electric charge (electrons in this example) generated by the organic photoelectric conversion section 20 on a side of the first surface 30A of the semiconductor substrate 30 to the side of the second surface 30B of the semiconductor substrate 30 via the through-electrode 34 and thus to increase the characteristics.

The lower end of the through-electrode 34 is coupled to a coupling section 41A in the wiring layer 41, and the coupling section 41A and the gate Gamp of the amplifier transistor AMP are coupled via a lower first contact 45. The coupling section 41A and the floating diffusion FD1 (region 36B) are coupled to each other, for example, via a lower second contact 46. The upper end of the through-electrode 34 is coupled to the readout electrode 21A, for example, via a pad section 39A and an upper first contact 39C.

The through-electrode 34 is provided, for example, for each of the organic photoelectric conversion sections 20 in the respective imaging elements 10. The through-electrode 34 has a function as a connector for the organic photoelectric conversion section 20 and the gate Gamp of the amplifier transistor AMP and the floating diffusion FD1, and serves as a transmission path for the electric charge generated by the organic photoelectric conversion section 20.

A reset gate Grst of the reset transistor RST is disposed next to the floating diffusion FD1 (one source/drain region 36B of the reset transistor RST). This enables the reset transistor RST to reset the electric charge accumulated in the floating diffusion FD1.

In the imaging element 10 according to the present embodiment, light having entered the organic photoelectric conversion section 20 from a side of the upper electrode 26 is absorbed by the photoelectric conversion layer 24. Excitons generated thereby move to an interface between an electron donor and an electron acceptor constituting the photoelectric conversion layer 24, and undergo exciton separation. In other words, the excitons are dissociated into electrons and holes. The electric charge (electrons and holes) generated here is transported to different electrodes by diffusion due to a carrier concentration difference and by an internal electric field caused by a work function difference between the anode (upper electrode 26 in this example) and the cathode (lower electrode 21 in this example). The transported electric charge is detected as a photocurrent. In addition, the application of a potential between the lower electrode 21 and the upper electrode 26 makes it possible to control the transport directions of electrons and holes.

The following describes configurations, materials, and the like of the respective sections.

The imaging element 10 constitutes single pixels (unit pixels P) that are repeatedly arranged in array in a pixel section 100A of the imaging device 1 illustrated in FIG. 22, for example. In the pixel section 100A, pixel units 1a each including four pixels arranged in two rows×two columns, for example, serve as a repeating unit, as illustrated in FIG. 2, and are repeatedly arranged in an array shape including a row direction and a column direction.

The organic photoelectric conversion section 20 is an organic photoelectric conversion element that absorbs green light corresponding to a selective wavelength range, e.g., a portion or the whole of a wavelength range of 450 nm or more and 650 nm or less to generate excitons.

The lower electrode 21 corresponds to a specific example of a “first electrode” of the present disclosure. As described above, the lower electrode 21 is configured by the readout electrode 21A and the accumulation electrode 21B that are separately formed. The readout electrode 21A is provided to transfer the electric charge (electrons in this example) generated in the organic photoelectric conversion layer 24 to the floating diffusion FD1. The readout electrode 21A is coupled to the floating diffusion FD1, for example, via the upper first contact 39C, the pad section 39A, the through-electrode 34, the coupling section 41A, and the lower second contact 46. The accumulation electrode 21B is provided to accumulate, as signal charge, the electrons of the electric charge generated in the photoelectric conversion layer 24, in the charge accumulation layer 23. The accumulation electrode 21B is provided in a region that is opposed to light-receiving surfaces of the inorganic photoelectric conversion sections 32B and 32R formed in the semiconductor substrate 30 and covers these light-receiving surfaces. It is preferable that the accumulation electrode 21B be larger than the readout electrode 21A. This makes it possible to accumulate more electric charge.

The lower electrode 21 is configured by an electrically-conductive film having light transmissivity. The lower electrode 21 is configured by, for example, ITO (indium tin oxide). However, in addition to this ITO, a tin oxide (SnO₂)-based material doped with a dopant or a zinc oxide-based material obtained by adding a dopant to zinc oxide (ZnO) may be used as a material constituting the lower electrode 21. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, CuI, InSbO₄, ZnMgO, CuInO₂, MgIN₂O₄, CdO, ZnSnO₃, or the like may also be used in addition thereto.

The charge accumulation layer 23 corresponds to a specific example of a “third semiconductor layer” of the present disclosure. The charge accumulation layer 23 is provided in a lower layer of the photoelectric conversion layer 24. Specifically, the charge accumulation layer 23 is provided between the insulating layer 22 and the photoelectric conversion layer 24. The charge accumulation layer 23 is provided to accumulate the signal charge generated in the photoelectric conversion layer 24. In the present embodiment, electrons are used as signal charge. It is therefore preferable that the charge accumulation layer 23 be formed by using an n-type semiconductor material. For example, it is preferable to use a material having, at the lowest edge of a conduction band, a shallower energy level than the work function of the lower electrode 21. Examples of such an n-type semiconductor material include IGZO (In—Ga—Zn—O-based oxide semiconductor), ZTO (Zn—Sn—O-based oxide semiconductor), IGZTO (In—Ga—Zn—Sn—O-based oxide semiconductor), GTO (Ga—Sn—O-based oxide semiconductor), IGO (In—Ga—O-based oxide semiconductor), and the like. It is preferable to use at least one of the oxide semiconductor materials described above for the charge accumulation layer 23. Among them, IGZO is favorably used. The charge accumulation layer 23 has a thickness of 30 nm or more and 200 nm or less, for example. The charge accumulation layer 23 preferably has a thickness of 60 nm or more and 150 nm or less. Providing the charge accumulation layer 23 configured by the materials described above in a lower layer of the photoelectric conversion layer 24 makes it possible to prevent electric charge from being recombined during electric charge accumulation and thus to increase transfer efficiency.

The photoelectric conversion layer 24 is provided to convert light energy into electric energy. The photoelectric conversion layer 24 includes, for example, two or more types of organic materials (p-type semiconductor material or n-type semiconductor material) that each function as a p-type semiconductor or an n-type semiconductor. The photoelectric conversion layer 24 has, in the layer, the junction surface (p/n junction surface) between the p-type semiconductor material and the n-type semiconductor material. The p-type semiconductor relatively functions as an electron donor, and the n-type semiconductor relatively functions as an electron acceptor. The photoelectric conversion layer 24 provides a field in which excitons generated in absorbing light are separated into electrons and holes. Specifically, excitons are separated into electrons and holes at the interface (p/n junction surface) between the electron donor and the electron acceptor.

The photoelectric conversion layer 24 may include an organic material or a so-called dye material in addition to the p-type semiconductor material and the n-type semiconductor material. The organic material or the dye material photoelectrically converts light in a predetermined wavelength range and transmits light in another wavelength range. In a case where the photoelectric conversion layer 24 is formed by using the three types of organic materials including a p-type semiconductor material, an n-type semiconductor material, and a dye material, it is preferable that the p-type semiconductor material and the n-type semiconductor material be materials each having light transmissivity in a visible region (e.g., 450 nm or more and 800 nm or less). The photoelectric conversion layer 24 has a thickness of 50 nm or more and 500 nm or less, for example.

It is preferable that the photoelectric conversion layer 24 according to the present embodiment include an organic material and have absorption between the visible light and the near-infrared light. Examples of an organic material constituting the photoelectric conversion layer 24 include quinacridone, boron chloride subphthalocyanine, pentacene, benzothienobenzothiophene, fullerene, and derivatives thereof. The photoelectric conversion layer 24 is configured by two or more of the organic materials described above in combination. The organic materials described above function as a p-type semiconductor or an n-type semiconductor depending on the combination.

It is to be noted that the organic materials constituting the photoelectric conversion layer 24 are not particularly limited. For example, any one of naphthalene, anthracene, phenantherene, tetracene, pyrene, perylene, and fluoranthene or derivatives thereof is favorably used in addition to the organic materials described above. Alternatively, a polymer such as phenylenevinylene, fluorene, carbazole, indole, pyrene, pyrrole, picoline, thiophene, acetylene, or diacetylene or a derivative thereof may be used. Additionally, it may be possible to favorably use a metal complex dye, a cyanine-based dye, a merocyanine-based dye, a phenylxanthene-based dye, a triphenylmethane-based dye, a rhodacyanine-based dye, a xanthene-based dye, a macrocyclic azaannulene-based dye, an azulene-based dye, naphthoquinone, an anthraquinone-based dye, a chain compound in which a fused polycyclic aromatic group such as anthracene and pyrene and an aromatic ring or a heterocyclic compound are fused, a cyanine-like dye bonded by two nitrogen-containing hetero rings such as quinoline, benzothiazole, and benzoxazole that have a squarylium group and a croconic methine group as a bonded chain or by a squarylium group and a croconic methine group, or the like. It is to be noted that a dithiol metal complex-based dye, a metallophthalocyanine dye, a metalloporphyrine dye, or a ruthenium complex dye is preferable as the metal complex dye described above, but this is not limitative.

The work function adjustment layer 25 corresponds to a specific example of a “first semiconductor layer” of the present disclosure. The work function adjustment layer 25 is provided in an upper layer of the photoelectric conversion layer 24. The work function adjustment layer 25 is provided to change an internal electric field in the photoelectric conversion layer 24 to rapidly transfer and accumulate the signal charge generated by the photoelectric conversion layer 24 to and in the charge accumulation layer 23. The work function adjustment layer 25 has light transmissivity. It is preferable that the work function adjustment layer 25 have, for example, a light absorptivity of 10% or less for visible light. As described above, the work function adjustment layer 25 has an electron affinity of 4.5 eV or more and 6.0 eV or less. The work function adjustment layer 25 includes two types of materials having a predetermined electron affinity and ionization potential. The two types of materials correspond to carbon-containing compounds (a first carbon-containing compound and a second carbon-containing compound).

The first carbon-containing compound has an electron affinity greater than 4.8 eV or an electron affinity greater than a work function of the upper electrode 26, for example. The second carbon-containing compound has an ionization potential greater than 5.5 eV, for example. It is to be noted that the electron affinity corresponds to an energy difference between a LUMO level and a vacuum level.

Examples of the first carbon-containing compound include a hexaazatriphenylene derivative such as dipyrazino [2,3-f: 2′,3′-h] quinoxaline-2,3,6,7,10,11-hexacarbonitrile (HATCN). Examples of the second carbon-containing compound include a fullerene derivative such as fullerene C₆₀ and fullerene C₇₀, 2,9-bis(naphthalen-2-yl)-4,7-diphenyl-1,10-phenanthroline (NBphen), a naphthalene diimide derivative (e.g., NDI-35), a carbazole derivative (CzBDF), an aromatic amine-based material (IT-102), an indolocarbazole derivative (e.g., PC-IC), an acene derivative, a phenanthrene derivative, a perylene derivative, a chrysene derivative, a fluoranthene derivative, a phthalocyanine derivative, a subphthalocyanine derivative, a hexaazatriphenylene derivative, a metal complex containing a heterocyclic compound as a ligand, a thiophene derivative, a thienothiophene derivative, and a thienoacene derivative. Alternative examples thereof include an organometal complex and an organic molecule including, as a portion of a molecular skeleton, a heterocycle containing nitrogen (N), such as pyridine, pyrazine, pyrimidine, triazine, quinoline, quinoxaline, isoquinoline, acridine, phenazine, indole, imidazole, benzimidazole, phenanthroline, tetrazole, naphthalenetetracarboxylic acid diimide, naphthalenedicarboxylic acid monoimide, hexaazatriphenylene, and hexaazatrinaphthylene.

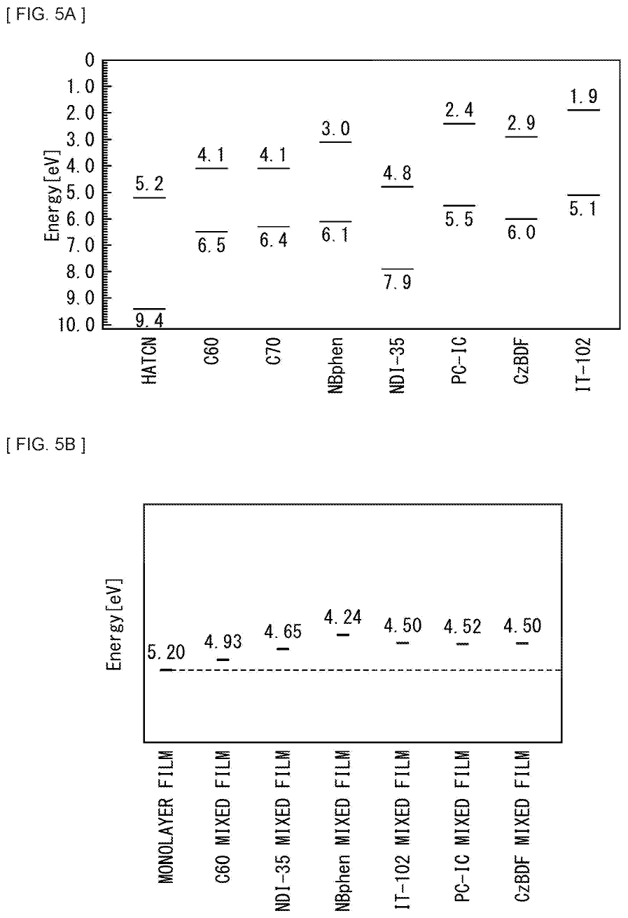

FIG. 5A illustrates energy levels of respective monolayer films of the first carbon-containing compound and the second carbon-containing compound described above. FIG. 5B illustrates energy levels of a monolayer film of the first carbon-containing compound (HATCN) described above and of a mixed film of the first carbon-containing compound (HATCN) and the second carbon-containing compound described above. It is to be noted that the energy levels of HATCN, C₆₀ fullerene, and C₇₀ fullerene illustrated in FIGS. 5A and 5B are each a value calculated using ultraviolet photoelectron spectroscopy (UPS) and low-energy inverse photoelectron spectroscopy (LEIPES). Energy levels of NBphen, NDI-35, PC-IC, CzBDF and IT-102 illustrated in FIGS. 5A and 5B are each a value calculated from an optical band gap.

The work function adjustment layer 25 can be formed, for example, as a mixed film in which the above-described first carbon-containing compound and the second carbon-containing compound are mixed. As can be appreciated from FIG. 5B, adopting the mixed film allows an electron affinity of the mixed film to be shifted in a direction of a smaller electron affinity, as compared with the monolayer film of the first carbon-containing compound described above, thus enabling formation of the work function adjustment layer 25 having an electron affinity of 4.5 eV or more and 6.0 eV or less. In addition, the work function adjustment layer 25 (mixed film) has a electron affinity greater than the work function of the upper electrode 26, for example. This makes it possible to reduce generation of a dark current, for example. The mixed film (work function adjustment layer 25) has an amorphous grain size or a crystalline grain size of 10 nm or less. In addition, the mixed film (work function adjustment layer 25) has an arithmetic mean roughness (Ra) of 0.8 nm or less. In addition, adhesiveness of the entire organic photoelectric conversion section 20 including the work function adjustment layer 25 is 0.05 KN/m or more. This makes the work function adjustment layer 25 and the upper electrode 26 less likely to undergo occurrence of film detachment, thus allowing for improved manufacturing yield. In addition, setting the mixing ratio between the first carbon-containing compound and the second carbon-containing compound to 0.1 or more and 10 or less makes it possible to improve afterimage characteristics.

The work function adjustment layer 25 may be formed as a stacked film of a layer including the first carbon-containing compound and a layer including the second carbon-containing compound, for example. In that case, it is preferable to stack the layer including the first carbon-containing compound/the layer including the second carbon-containing compound in this order from a side of the photoelectric conversion layer 24, for example, in consideration of adhesiveness between the work function adjustment layer 25 and the upper electrode 26. The work function adjustment layer 25 has a thickness of 0.5 nm or more and 30 nm or less, for example.

Another organic layer may be provided between the photoelectric conversion layer 24 and the lower electrode 21 (e.g., between the charge accumulation layer 23 and the photoelectric conversion layer 24) and between the photoelectric conversion layer 24 and the upper electrode 26 (e.g., between the photoelectric conversion layer 24 and the work function adjustment layer 25). Specifically, for example, the charge accumulation layer 23, a hole blocking layer, the photoelectric conversion layer 24, an electron blocking layer, the work function adjustment layer 25, and the like may be stacked in order from a side of the lower electrode 21. Further, an underlying layer and a hole transport layer may be provided between the lower electrode 21 and the photoelectric conversion layer 24, and a buffer layer or the like may be provided between the photoelectric conversion layer 24 and the upper electrode 26. It is to be noted that, in a case where a buffer layer is provided between the photoelectric conversion layer 24 and the upper electrode 26, e.g., adjacent to the work function adjustment layer 25, the buffer layer preferably has a shallower energy level than a work function of the work function adjustment layer 25. In addition, the buffer layer is preferably formed using an organic material having a glass-transition point higher than 100° C., for example.

In the same manner as the lower electrode 21, the upper electrode 26 is configured by an electrically-conductive film having light transmissivity. In the imaging device 1, in which the imaging element 10 is used as the unit pixel P, the upper electrode 26 may be separated for each of the unit pixels P, or may be formed as an electrode common to each of the unit pixels P. The upper electrode 26 has a work function smaller than the work function of the work function adjustment layer 25, for example. The upper electrode 26 has a thickness of 10 nm to 200 nm, for example.

The fixed charge layer 28A may be a film having a positive fixed electric charge or a film having a negative electric fixed charge. Examples of a material of the film having a negative fixed electric charge include hafnium oxide, aluminum oxide, zirconium oxide, tantalum oxide, and titanium oxide. In addition, examples of a material other than those mentioned above include lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, or an aluminum oxynitride film.

The fixed charge layer 28A may have a configuration in which two or more types of films are stacked. This makes it possible to further enhance a function as the hole accumulation layer, for example, in a case of the film having a negative fixed electric charge.

A material of the dielectric layer 28B is not particularly limited, and the dielectric layer 28B is formed by, for example, a silicon oxide film, TEOS, a silicon nitride film, a silicon oxynitride film, or the like.

For example, the interlayer insulating layer 29 is configured by a monolayer film of one of silicon oxide, silicon nitride, silicon oxynitride, and the like, or alternatively is configured by a stacked film of two or more thereof.

A shield electrode 29X is provided, together with the lower electrode 21, on the interlayer insulating layer 29. The shield electrode 29X is provided to prevent capacitive coupling between the pixel units 1a adjacent to each other. For example, the shield electrode 29X is provided around the pixel unit 1a including four pixels arranged in two rows×two columns, and receives application of a fixed potential. The shield electrode 29X further extends between pixels adjacent to each other in the row direction (Z-axis direction) and the column direction (X-axis direction) in the pixel unit 1a.

The insulating layer 22 is provided to electrically separate the accumulation electrode 21B and the charge accumulation layer 23 from each other. The insulating layer 22 is provided on the interlayer insulating layer 29, for example, to cover the lower electrode 21. As described above, the insulating layer 22 is provided with an opening 22H on the readout electrode 21A, and the readout electrode 21A and the charge accumulation layer 23 are electrically coupled to each other via the opening 22H. The insulating layer 22 can be formed using a material similar to that of the interlayer insulating layer 29, for example, and is configured by, for example, a monolayer film of one of silicon oxide, silicon nitride, silicon oxynitride (SiON), and the like, or a stacked film of two or more thereof. The insulating layer 22 has a thickness of 20 nm to 500 nm, for example.

The semiconductor substrate 30 is configured by an n-type silicone (Si) substrate, for example, and includes a p-well 31 in a predetermined region. The second surface 30B of the p-well 31 is provided with the above-described transfer transistors Tr2 and Tr3, the amplifier transistor AMP, the reset transistor RST, the selection transistor SEL, and the like. In addition, a peripheral part of the semiconductor substrate 30 is provided with a peripheral circuit section 130 (see, e.g., FIG. 22) including a logic circuit, or the like.

The reset transistor RST (reset transistor Tr1rst) resets electric charge transferred from the organic photoelectric conversion section 20 to the floating diffusion FD1, and is configured by a MOS transistor, for example. Specifically, the reset transistor Tr1rst is configured by the reset gate Grst, a channel formation region 36A, and the source/drain regions 36B and 36C. The reset gate Grst is coupled to a reset line RST1. The one source/drain region 36B of the reset transistor Tr1rst also serves as the floating diffusion FD1. Another source/drain region 36C constituting the reset transistor Tr1rst is coupled to a power supply line VDD.

The amplifier transistor AMP is a modulation element that modulates, to a voltage, the amount of electric charge generated by the organic photoelectric conversion section 20, and is configured by a MOS transistor, for example. Specifically, the amplifier transistor AMP is configured by the gate Gamp, a channel formation region 35A, and the source/drain regions 35B and 35C. The gate Gamp is coupled to the readout electrode 21A and the one source/drain region 36B (floating diffusion FD1) of the reset transistor Tr1rst via the lower first contact 45, the coupling section 41A, the lower second contact 46, the through-electrode 34, and the like. In addition, the one source/drain region 35B shares a region with the other source/drain region 36C constituting the reset transistor Tr1rst, and is coupled to the power supply line VDD.

The selection transistor SEL (a selection transistor TR1sel) is configured by a gate Gsel, a channel formation region 34A, and source/drain regions 34B and 34C. The gate Gsel is coupled to a selection line SEL1. In addition, the one source/drain region 34B shares a region with the other source/drain region 35C constituting the amplifier transistor AMP, and the other source/drain region 34C is coupled to a signal line (data output line) VSL1.

Each of the inorganic photoelectric conversion sections 32B and 32R has a p-n junction in a predetermined region of the semiconductor substrate 30. The inorganic photoelectric conversion sections 32B and 32R each enable light to be dispersed in the vertical direction by utilizing a difference in wavelengths of light beams to be absorbed in accordance with the light incidence depth in a silicon substrate. The inorganic photoelectric conversion section 32B selectively detects, for example, blue light to accumulate the signal charge corresponding to blue. The inorganic photoelectric conversion section 32B is installed at a depth that enables the blue light to be photoelectrically converted efficiently. The inorganic photoelectric conversion section 32R selectively detects, for example, red light to accumulate the signal charge corresponding to red. The inorganic photoelectric conversion section 32R is installed at a depth that enables the red light to be photoelectrically converted efficiently. It is to be noted that blue (B) is a color corresponding, for example, to a wavelength range of 450 nm to 495 nm and red (R) is a color corresponding, for example, to a wavelength range of 620 nm to 750 nm. It is sufficient for each of the inorganic photoelectric conversion sections 32B and 32R to be able to detect light in a portion or the whole of each wavelength range.

The inorganic photoelectric conversion section 32B includes, for example, a p+ region serving as a hole accumulation layer and an n region serving as an electron accumulation layer. The inorganic photoelectric conversion section 32R includes, for example, a p+ region serving as a hole accumulation layer and an n region serving as an electron accumulation layer (has a p-n-p stacked structure). The n region of the inorganic photoelectric conversion section 32B is coupled to the vertical transfer transistor Tr2. The p+ region of the inorganic photoelectric conversion section 32B is bent along the transfer transistor Tr2, and leads to the p+ region of the inorganic photoelectric conversion section 32R.

The transfer transistor Tr2 (transfer transistor TR2trs) is provided to transfer, to the floating diffusion FD2, signal charge (electrons in this example) corresponding to blue that has been generated and accumulated in the inorganic photoelectric conversion section 32B. The inorganic photoelectric conversion section 32B is formed at a deep position from the second surface 30B of the semiconductor substrate 30, and it is thus preferable that the transfer transistor TR2trs of the inorganic photoelectric conversion section 32B be configured by a vertical transistor. In addition, the transfer transistor TR2trs is coupled to a transfer gate line TG2. Further, the floating diffusion FD2 is provided in the region 37C near a gate Gtrs2 of the transfer transistor TR2trs. The electric charge accumulated in the inorganic photoelectric conversion section 32B is read to the floating diffusion FD2 via a transfer channel formed along the gate Gtrs2.

The transfer transistor Tr3 (a transfer transistor TR3trs) transfers, to the floating diffusion FD3, the signal charge (electrons in this example) corresponding to red that has been generated and accumulated in the inorganic photoelectric conversion section 32R. The transfer transistor Tr3 (transfer transistor TR3trs) is configured by, for example, a MOS transistor. In addition, the transfer transistor TR3trs is coupled to a transfer gate line TG3. Further, the floating diffusion FD3 is provided in the region 38C near a gate Gtrs3 of the transfer transistor TR3trs. The electric charge accumulated in the inorganic photoelectric conversion section 32R is read to the floating diffusion FD3 via a transfer channel formed along the gate Gtrs3.

The side of the second surface 30B of the semiconductor substrate 30 is further provided with a reset transistor TR2rst, an amplifier transistor TR2amp, and a selection transistor TR2sel constituting the controller of the inorganic photoelectric conversion section 32B. In addition, there are provided a reset transistor TR3rst, an amplifier transistor TR3amp, and a selection transistor TR3sel constituting the controller of the inorganic photoelectric conversion section 32R.

The reset transistor TR2rst is configured by a gate, a channel formation region, and source/drain regions. The gate of the reset transistor TR2rst is coupled to a reset line RST2, and the one source/drain region of the reset transistor TR2rst is coupled to the power supply line VDD. The other source/drain region of the reset transistor TR2rst also serves as the floating diffusion FD2.

The amplifier transistor TR2amp is configured by a gate, a channel formation region, and source/drain regions. The gate is coupled to the other source/drain region (floating diffusion FD2) of the reset transistor TR2rst. In addition, the one source/drain region constituting the amplifier transistor TR2amp shares a region with the one source/drain region constituting the reset transistor TR2rst, and is coupled to the power supply line VDD.

The selection transistor TR2sel is configured by a gate, a channel formation region, and source/drain regions. The gate is coupled to a selection line SEL2. In addition, the one source/drain region constituting the selection transistor TR2sel shares a region with the other source/drain region constituting the amplifier transistor TR2amp. The other source/drain region constituting the selection transistor TR2sel is coupled to a signal line (data output line) VSL2.

The reset transistor TR3rst is configured by a gate, a channel formation region, and source/drain regions. The gate of the reset transistor TR3rst is coupled to a reset line RST3, and the one source/drain region constituting the reset transistor TR3rst is coupled to the power supply line VDD. The other source/drain region constituting the reset transistor TR3rst also serves as the floating diffusion FD3.

The amplifier transistor TR3amp is configured by a gate, a channel formation region, and source/drain regions. The gate is coupled to the other source/drain region (floating diffusion FD3) constituting the reset transistor TR3rst. In addition, the one source/drain region constituting the amplifier transistor TR3amp shares a region with the one source/drain region constituting the reset transistor TR3rst, and is coupled to the power supply line VDD.

The selection transistor TR3sel is configured by a gate, a channel formation region, and source/drain regions. The gate is coupled to a selection line SEL3. In addition, the one source/drain region constituting the selection transistor TR3sel shares a region with the other source/drain region constituting the amplifier transistor TR3amp. The other source/drain region constituting the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit 111 constituting a drive circuit. The signal lines (data output lines) VSL1, VSL2, and VSL3 are coupled to a horizontal drive circuit 113 constituting the drive circuit.

The lower first contact 45, the lower second contact 46, the upper first contact 39C, and an upper second contact 39D each include, for example, a doped silicon material such as PDAS (Phosphorus Doped Amorphous Silicon) or a metal material such as aluminum (Al), tungsten (W), titanium (Ti), cobalt (Co), hafnium (Hf), or tantalum (Ta).

The protective layer 51 is provided above the organic photoelectric conversion section 20, and is configured by a material having light transmissivity. Specifically, the protective layer 51 is configured by, for example, a monolayer film including any of silicon oxide, silicon nitride, silicon oxynitride, and the like, or a stacked film including two or more thereof. This protective layer 51 has a thickness of 100 nm to 30000 nm, for example.

The light-blocking film 52 is provided in the protective layer 51 to cover the readout electrode 21A, for example. Examples of a material of the light-blocking film 52 include tungsten (W), titanium (Ti), titanium nitride (TiN), or aluminum (Al). The light-blocking film 52 is configured, for example, as a stacked film of W/TiN/Ti or a monolayer film of W. The light-blocking film 52 has a thickness of 50 nm or more and 400 nm or less, for example.

The pixel section 100A is provided, for example, with the on-chip lens 53 on the protective layer 51 for each of the unit pixels P. The on-chip lens 53 condenses incident light on the respective light-receiving surfaces of the organic photoelectric conversion section 20, the inorganic photoelectric conversion section 32B, and the inorganic photoelectric conversion section 32R.

### (1-2. Method of Manufacturing Imaging Element)

The imaging element 10 according to the present embodiment can be manufactured, for example, as follows.

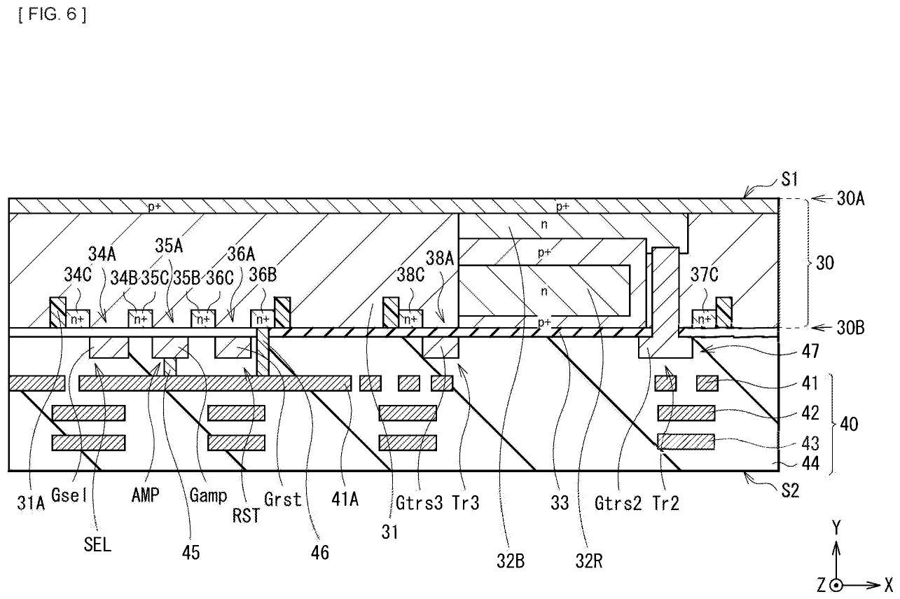

FIGS. 6 to 12 illustrate a method of manufacturing the imaging element 10 in the order of steps. First, as illustrated in FIG. 6, for example, the p-well 31 is formed, as a well of a first electrical conduction type, in the semiconductor substrate 30. The inorganic photoelectric conversion sections 32B and 32R of a second electrical conduction type (e.g., n type) are formed in this p-well 31. A p+ region is formed near the first surface 30A of the semiconductor substrate 30.

As also illustrated in FIG. 6, for example, n+ regions that serve as the floating diffusions FD1 to FD3 are formed on the second surface 30B of the semiconductor substrate 30, and a gate insulating layer 33 and a gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. This forms the transfer transistor Tr2, the transfer transistor Tr3, the selection transistor SEL, the amplifier transistor AMP, and the reset transistor RST. Further, the multilayer wiring layer 40 is formed on the second surface 30B of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As the base of the semiconductor substrate 30, for example, an SOI (Silicon on Insulator) substrate is used in which the semiconductor substrate 30, an embedded oxide film (unillustrated), and a holding substrate (unillustrated) are stacked. Although unillustrated in FIG. 6, the embedded oxide film and the holding substrate are joined to the first surface 30A of the semiconductor substrate 30. After ion implantation, annealing treatment is performed.

Next, a support substrate (unillustrated), another semiconductor base, or the like is joined to the side of the second surface 30B (side of the multilayer wiring layer 40) of the semiconductor substrate 30, and the substrate is turned upside down. Subsequently, the semiconductor substrate 30 is separated from the embedded oxide film and the holding substrate of the SOI substrate to expose the first surface 30A of the semiconductor substrate 30. The above-described steps can be performed with a technique used in a normal CMOS process such as ion implantation and CVD (Chemical Vapor Deposition).

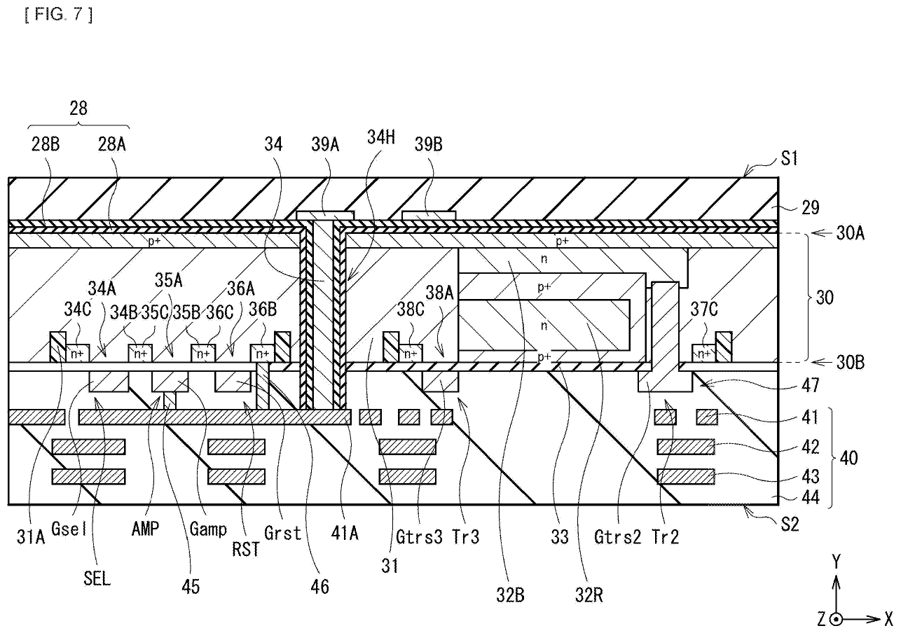

Next, as illustrated in FIG. 7, the semiconductor substrate 30 is worked from the side of the first surface 30A, for example, by dry etching to form, for example, an annular opening 34H. As for a depth, the opening 34H extends from the first surface 30A to the second surface 30B of the semiconductor substrate 30, and reaches, for example, the coupling section 41A, as illustrated in FIG. 7.

Subsequently, for example, the negative fixed charge layer 28A is formed on the first surface 30A of the semiconductor substrate 30 and the side surface of the opening 34H. Two or more types of films may be stacked as the negative fixed charge layer 28A. This makes it possible to further enhance a function as a hole accumulation layer. The dielectric layer 28B is formed after the negative fixed charge layer 28A is formed. Next, the pad sections 39A and 39B are formed at predetermined positions on the dielectric layer 28B. Thereafter, the interlayer insulating layer 29 is formed on the dielectric layer 28B and the pad sections 39A and 39B, and a surface of the interlayer insulating layer 29 is planarized by using a CMP (Chemical Mechanical Polishing) method.

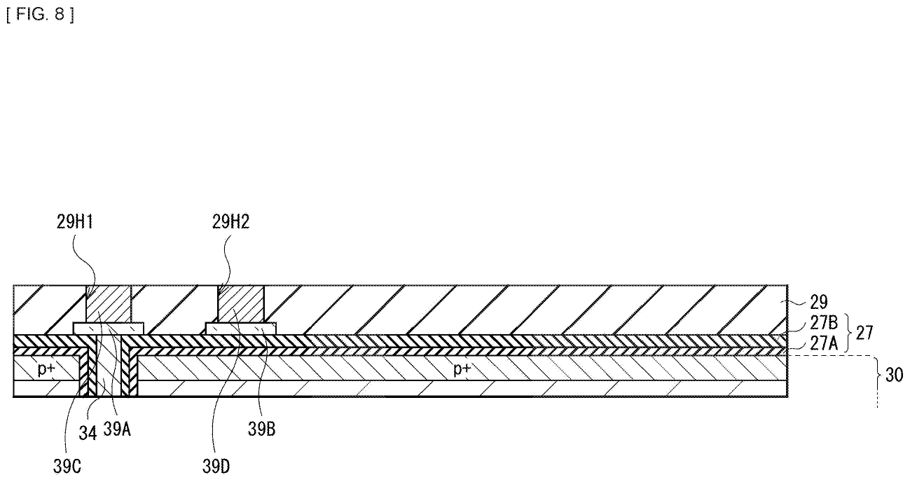

Subsequently, as illustrated in FIG. 8, openings 29H1 and 29H2 are respectively formed above the pad sections 39A and 39B. Thereafter, these openings 29H1 and 29H2 are filled, for example, with electrically conductive materials such as Al to form the upper first contact 39C and the upper second contact 39D.

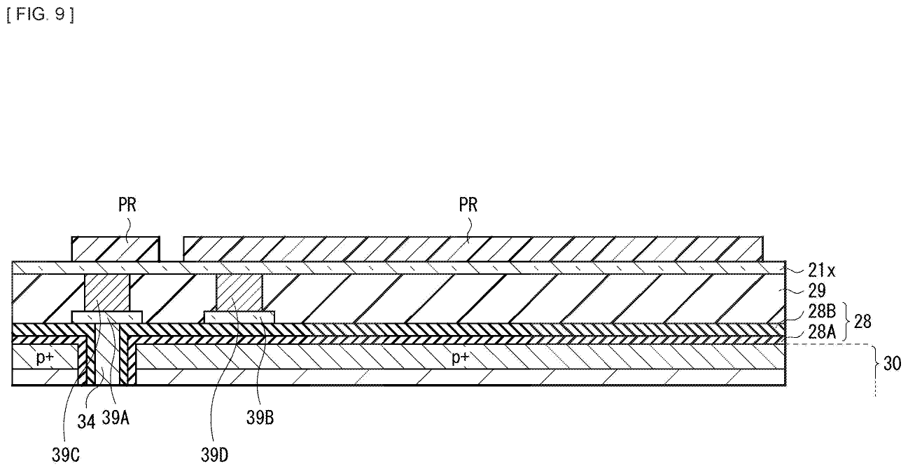

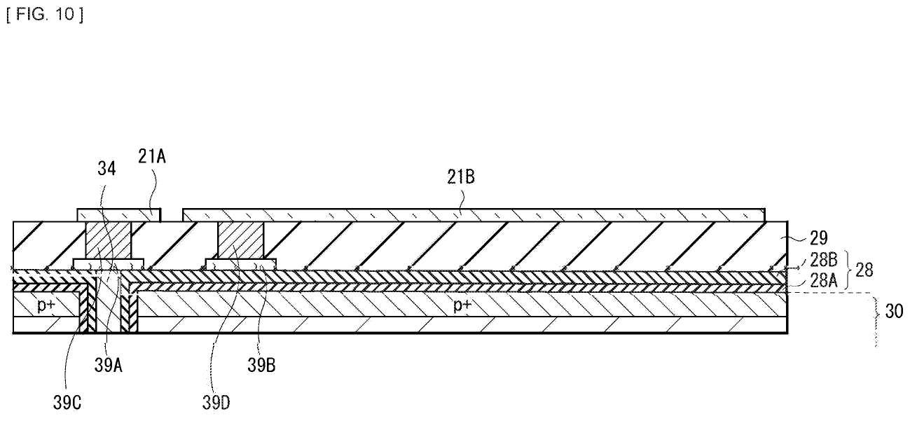

Next, as illustrated in FIG. 9, an electrically-conductive film 21x is formed on the interlayer insulating layer 29. Thereafter, a photoresist PR is formed at a predetermined position on the electrically-conductive film 21x. Thereafter, the readout electrode 21A and the accumulation electrode 21B illustrated in FIG. 10 are patterned by etching and removing the photoresist PR.

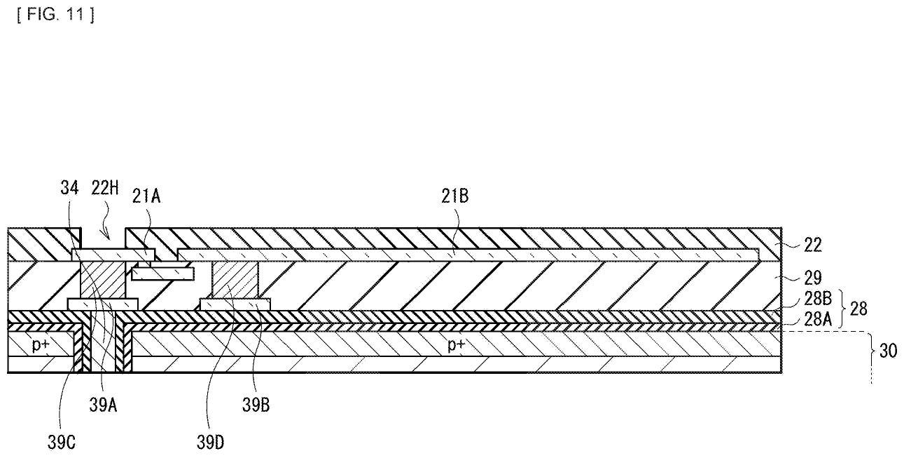

Subsequently, as illustrated in FIG. 11, the insulating layer 22 is formed on the interlayer insulating layer 29, the readout electrode 21A, and the accumulation electrode 21B. Thereafter, the opening 22H is provided above the readout electrode 21A.

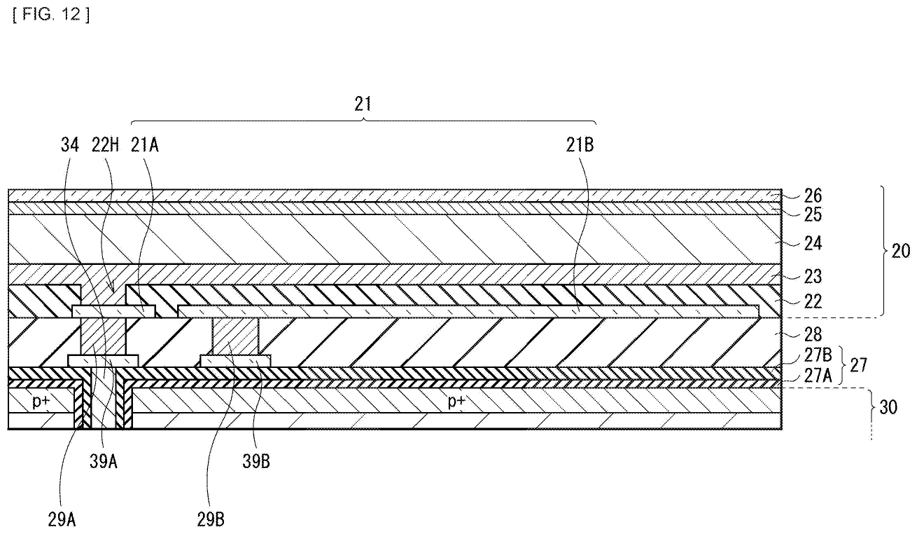

Next, as illustrated in FIG. 12, the charge accumulation layer 23, the photoelectric conversion layer 24, the work function adjustment layer 25, and the upper electrode 26 are formed on the insulating layer 22. It is to be noted that, in a case where the charge accumulation layer 23 and the work function adjustment layer 25 are formed by using organic materials, it is desirable to continuously form the charge accumulation layer 23, the photoelectric conversion layer 24, and the work function adjustment layer 25 in a vacuum step (by a vacuum-consistent process). In addition, the method of forming the photoelectric conversion layer 24 is not necessarily limited to a technique that uses a vacuum deposition method. Another method may be used such as a spin coating technique or a printing technique, for example. Finally, the protective layer 51 including the light-blocking film 52 and the on-chip lens 53 are formed above the organic photoelectric conversion section 20. Thus, the imaging element 10 illustrated in FIG. 1 is completed.

When light enters the organic photoelectric conversion section 20 via the on-chip lens 53 in the imaging element 10, the light passes through the organic photoelectric conversion section 20 and the inorganic photoelectric conversion sections 32B and 32R in this order. While the light passes through the organic photoelectric conversion section 20 and the inorganic photoelectric conversion sections 32B and 32R, the light is photoelectrically converted for each of color light beams of green, blue, and red. The following describes operations of acquiring signals of the respective colors.

### (Acquisition of Green Color Signal by Organic Photoelectric Conversion Section 20)

First, green light of the light beams having entered the imaging element 10 is selectively detected (absorbed) and photoelectrically converted by the organic photoelectric conversion section 20.

The organic photoelectric conversion section 20 is coupled to the gate Gamp of the amplifier transistor AMP and the floating diffusion FD1 via the through-electrode 34. Thus, electrons of electron-hole pairs generated by the organic photoelectric conversion section 20 are taken out from the side of the lower electrode 21, transferred to the side of the second surface 30B of the semiconductor substrate 30 via the through-electrode 34, and accumulated in the floating diffusion FD1. At the same time, the amplifier transistor AMP modulates the amount of electric charge generated by the organic photoelectric conversion section 20 to a voltage.

In addition, the reset gate Grst of the reset transistor RST is disposed next to the floating diffusion FD1. This allows the reset transistor RST to reset the electric charge accumulated in the floating diffusion FD1.

Here, the organic photoelectric conversion section 20 is coupled to not only the amplifier transistor AMP, but also the floating diffusion FD1 via the through-electrode 34, thus enabling the reset transistor RST to easily reset the electric charge accumulated in the floating diffusion FD1.

In contrast, in a case where the through-electrode 34 and the floating diffusion FD1 are not coupled to each other, it is difficult to reset the electric charge accumulated in the floating diffusion FD1, thus causing a large voltage to be applied to pull out the electric charge to a side of the upper electrode 26. The photoelectric conversion layer 24 may therefore be damaged. In addition, a structure that enables resetting in a short period of time leads to an increase in dark noises, resulting in a trade-off. This structure is thus difficult.

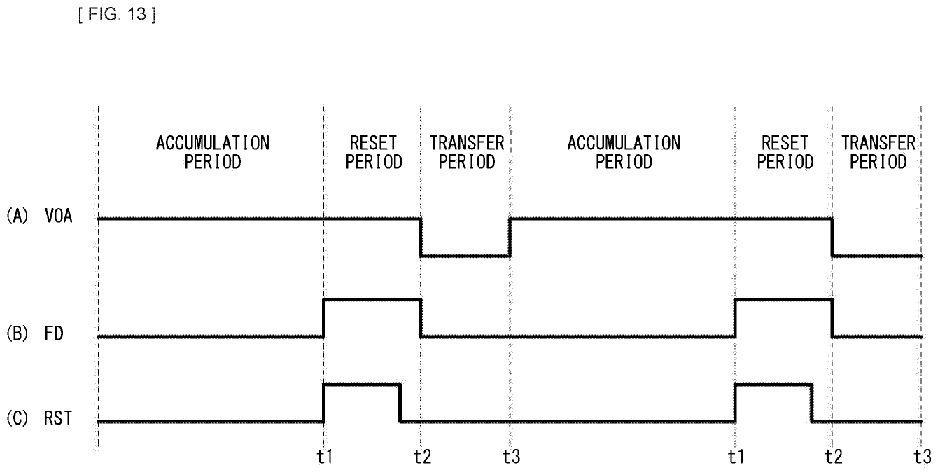

FIG. 13 illustrates an operation example of the imaging element 10. (A) illustrates the potential at the accumulation electrode 21B, (B) illustrates the potential at the floating diffusion FD1 (readout electrode 21A), and (C) illustrates the potential at the gate (Gsel) of the reset transistor TR1rst. In the imaging element 10, voltages are individually applied to the readout electrode 21A and the accumulation electrode 21B.

In the imaging element 10, the drive circuit applies a potential V1 to the readout electrode 21A and applies a potential V2 to the accumulation electrode 21B in an accumulation period. Here, it is assumed that the potentials V1 and V2 satisfy V2>V1. This allows electric charge (electrons in this example) generated through photoelectric conversion to be drawn to the accumulation electrode 21B and to be accumulated in a region of the charge accumulation layer 23 opposed to the accumulation electrode 21B (accumulation period). Incidentally, the value of the potential in the region of the charge accumulation layer 23 opposed to the accumulation electrode 21B becomes more negative with the passage of time of photoelectric conversion. It is to be noted that holes are sent from the upper electrode 26 to the drive circuit.

In the imaging element 10, a reset operation is performed in the latter half of the accumulation period. Specifically, at a timing t1, a scanning section changes the voltage of a reset signal RST from a low level to a high level. This brings the reset transistor TR1rst into an ON state in the unit pixel P. As a result, the voltage of the floating diffusion FD1 is set to the power supply line VDD, and the voltage of the floating diffusion FD1 is reset (reset period).

After the reset operation is completed, the electric charge is read. Specifically, the drive circuit applies a potential V3 to the readout electrode 21A and applies a potential V4 to the accumulation electrode 21B at a timing t2. Here, it is assumed that the potentials V3 and V4 satisfy V3<V4. This allows the electric charge (electrons in this example) accumulated in the region corresponding to the accumulation electrode 21B to be read from the readout electrode 21A to the floating diffusion FD1. In other words, the electric charge accumulated in the charge accumulation layer 23 is read to the controller (transfer period).

The drive circuit applies the potential V1 to the readout electrode 21A and applies the potential V2 to the accumulation electrode 21B again after the readout operation is completed. This allows electric charge (electrons in this example) generated through photoelectric conversion to be drawn to the accumulation electrode 21B and to be accumulated in the region of the photoelectric conversion layer 24 opposed to the accumulation electrode 21B (accumulation period).

### (Acquisition of Blue Color Signal and Red Color Signal by Inorganic Photoelectric Conversion Sections 32B and 32R)

Subsequently, the blue light and the red light of the light beams having passed through the organic photoelectric conversion section 20 are respectively absorbed and photoelectrically converted in order by the inorganic photoelectric conversion section 32B and the inorganic photoelectric conversion section 32R. In the inorganic photoelectric conversion section 32B, electrons corresponding to the incident blue light are accumulated in an n region of the inorganic photoelectric conversion section 32B, and the accumulated electrons are transferred to the floating diffusion FD2 by the transfer transistor Tr2. Likewise, in the inorganic photoelectric conversion section 32R, electrons corresponding to the incident red light are accumulated in an n region of the inorganic photoelectric conversion section 32R, and the accumulated electrons are transferred to the floating diffusion FD3 by the transfer transistor Tr3.

### (1-3. Workings and Effects)

In the imaging element 10 according to the present embodiment, the work function adjustment layer 25 is provided between the photoelectric conversion layer 24 and the upper electrode 26. The work function adjustment layer 25 has an electron affinity of 4.5 eV or more and 6.0 eV or less. The work function adjustment layer 25 is formed using the first carbon-containing compound and the second carbon-containing compound. The first carbon-containing compound has an electron affinity greater than 4.8 eV or an electron affinity greater than the work function of a second electrode. The second carbon-containing compound has an ionization potential greater than 5.5 eV. This allows for an improvement in adhesiveness between the photoelectric conversion layer 24 and the upper electrode 26 as well as an enhancement of an electric field to be applied to the photoelectric conversion layer 24. This is described below.

In general, many organic materials used in the work function adjustment layer contain a cyano group or a fluorine group. There is an issue in which these organic materials tend to cause aggregation between molecules, making it difficult to obtain a homogeneous film. Therefore, an imaging element including the layer including these organic materials may suffer lowered adhesiveness at the interface of a stacked film including different materials, thus causing lowered manufacturing yield due to film detachment, or the like. In addition, it is presumed that concentration of an electric field on a protrusion on the surface of the film may lead to tunneling conduction, thus causing deterioration of a dark current in withstanding a voltage.

In addition, the imaging element using the work function adjustment layer including these organic materials tends to have a low response speed after light irradiation due to insufficient obtainment of external quantum efficiency (EQE). One conceivable reason for this is that, in a process in which at least holes flowed from an adjacent electron blocking layer or photoelectric conversion layer are recombined at an interface with the work function adjustment layer, the work function adjustment layer including the organic material lacks an electric field to be substantially applied to the photoelectric conversion layer due to an increase in space charge near the interface as a result of speed-down of the recombination process or the carrier trapping at the interface.

In contrast, in the present embodiment, the first carbon-containing compound having an electron affinity greater than 4.8 eV or an electron affinity greater than the work function of the second electrode and the second carbon-containing compound having an ionization potential greater than 5.5 eV are used to provide the work function adjustment layer 25 having an electron affinity of 4.5 eV or more and 6.0 eV or less. This suppresses the aggregation of the first carbon-containing compound, for example, in the work function adjustment layer 25, thus improving adhesiveness between the photoelectric conversion layer 24 and the upper electrode 26. In addition, as compared with the case where only the first carbon-containing compound is used to form the work function adjustment layer, the electron affinity becomes small (e.g., 4.5 eV or more and 6.0 eV or less), thus enhancing an electric field to be substantially applied to the photoelectric conversion layer 24.

As described above, in the imaging element 10 of the present embodiment, the improvement in the adhesiveness between the photoelectric conversion layer 24 and the upper electrode 26 makes it possible to improve the manufacturing yield. In addition, the enhancement of an electric field to be applied to the photoelectric conversion layer 24 makes it possible to improve element characteristics. Specifically, for example, it is possible to reduce the generation of a dark current and to improve the response speed.

Next, descriptions are given of a second embodiment and Modification Examples 1 to 4 of the present disclosure. It is to be noted that components corresponding to those of the imaging element 10 of the foregoing first embodiment are denoted by the same reference numerals, and descriptions thereof are omitted.

### 2. Second Embodiment

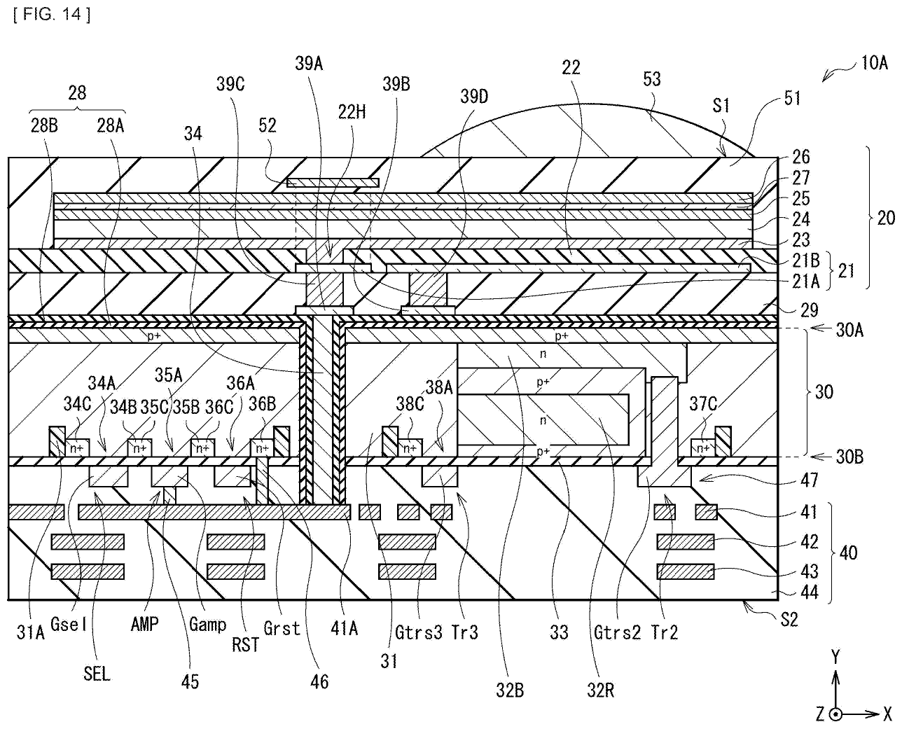

FIG. 14 illustrates a cross-sectional configuration of an imaging element (an imaging element 10A) according to a second embodiment of the present disclosure. In the same manner as the foregoing first embodiment, the imaging element 10A constitutes one pixel (unit pixel P) in an imaging device (imaging device 1; see FIG. 22) such as a CMOS image sensor used in an electronic apparatus such as a digital still camera or a video camera.

The imaging element 10A is a so-called vertical spectroscopic imaging element in which the one organic photoelectric conversion section 20 and two inorganic photoelectric conversion sections 32B and 32R are stacked in the vertical direction. The organic photoelectric conversion section 20 is provided on a side of a first surface (back surface) 30A of the semiconductor substrate 30. The inorganic photoelectric conversion sections 32B and 32R are formed to be embedded in the semiconductor substrate 30, and are stacked in a thickness direction of the semiconductor substrate 30. The imaging element 10A of the present embodiment is further provided with an electron injection promoting layer 27, having a predetermined in-gap level, between the work function adjustment layer 25 and the upper electrode 26 in the organic photoelectric conversion section 20.

The electron injection promoting layer 27 is provided to promote injection of electrons from the upper electrode 26, and is provided between the work function adjustment layer 25 and the upper electrode 26, as described above. In the electron injection promoting layer 27, an absolute value B of a difference between an ionization potential of the electron injection promoting layer 27 and a Fermi level of the upper electrode 26 is equal to or more than an absolute value A of a difference between an electron affinity of the electron injection promoting layer 27 calculated from an optical band gap and a Fermi level of the upper electrode 26. Alternatively, the electron injection promoting layer 27 has an in-gap level with a state density of 1/10000 or more with respect to a state density of the ionization potential of the electron injection promoting layer 27, near the Fermi level of the upper electrode 26. This increases the concentration of electrons in the work function adjustment layer 25, thus improving carrier conductivity at the interface between the photoelectric conversion layer 24 and the work function adjustment layer 25.

It may be possible to use, as a constituent material of the electron injection promoting layer 27, for example, the second carbon-containing compound constituting the work function adjustment layer 25. Specific examples thereof include [2,9-bis(naphthalen-2-yl)-4,7-diphenyl-1,10-phenanthroline] (NBphen) and a naphthalene diimide-based molecule (e.g., NDI-35). Additional examples of the constituent material of the electron injection promoting layer 27 include lithium, cesium, rubidium, lithium oxide, cesium carbonate, rubidium oxide, lithium fluoride, and cesium fluoride. The electron injection promoting layer 27 has a thickness of 0.5 nm or more and 10 nm or less, for example.

As described above, the imaging element 10A of the present embodiment is provided, between the work function adjustment layer 25 and the upper electrode 26, with the electron injection promoting layer 27 in which the absolute value B of the difference between the ionization potential of the electron injection promoting layer 27 and the Fermi level of the upper electrode 26 is equal to or more than the absolute value A of the difference between the electron affinity of the electron injection promoting layer 27 calculated from the optical band gap and the Fermi level of the upper electrode 26. In addition, the imaging element 10A of the present embodiment is provided, between the work function adjustment layer 25 and the upper electrode 26, with the electron injection promoting layer 27 having an in-gap level with a state density of 1/10000 or more with respect to the state density of the ionization potential of the electron injection promoting layer 27 near the Fermi level of the upper electrode 26.

As in the foregoing first embodiment, in the imaging element 10 that reads electrons as signal charge from the readout electrode 21A, holes generated in the photoelectric conversion layer 24 recombine with electrons injected from the upper electrode 26 at the interface between the work function adjustment layer 25 and the organic layer including the photoelectric conversion layer 24 adjacent to the work function adjustment layer 25. The occurrence of this recombination allows electrons (signal charge) to be efficiently read from the readout electrode 21A. The recombination of electrons and holes at the interface between the work function adjustment layer 25 and the organic layer including the photoelectric conversion layer 24 adjacent to the work function adjustment layer 25 depends on electric charge densities of holes and electrons.

In contrast, in the present embodiment, the above-described electron injection promoting layer 27 is provided between the work function adjustment layer 25 and the upper electrode 26, and thus the concentration of electrons in the work function adjustment layer 25 is increased, thus improving the carrier conductivity at the interface between the photoelectric conversion layer 24 and the work function adjustment layer 25. This further enhances an electric field to be applied to the photoelectric conversion layer 24. It is therefore possible to further improve the element characteristic, in addition to the effects of the foregoing first embodiment. Specifically, for example, it is possible to further improve the response speed as well as to improve the EQE.

### 3. Modification Examples

### 3-1. Modification Example 1

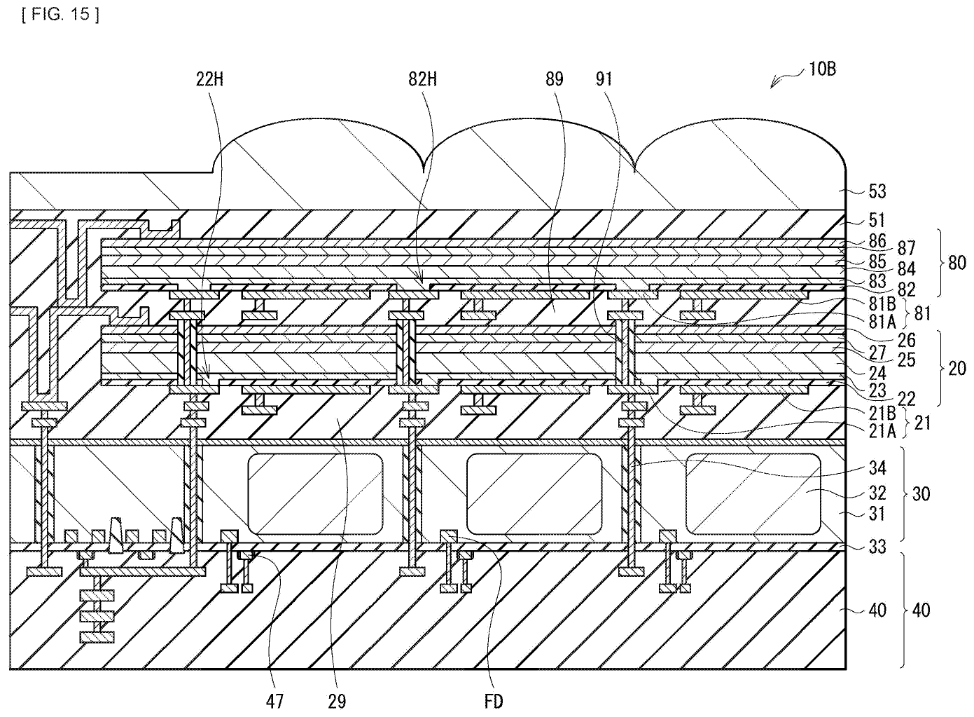

FIG. 15 schematically illustrates a cross-sectional configuration of an imaging element 10B according to Modification Example 1 of the present disclosure. In the same manner as the imaging element 10 of the foregoing first embodiment, the imaging element 10B is an imaging element such as a CMOS image sensor used in an electronic apparatus such as a digital still camera or a video camera, for example. In the imaging element 10B of the present modification example, two organic photoelectric conversion sections 20 and 80 and one inorganic photoelectric conversion section 32 are stacked in the vertical direction.

The organic photoelectric conversion sections 20 and 80 and the inorganic photoelectric conversion section 32 selectively detect light beams in wavelength ranges different from each other to perform photoelectric conversion. For example, the organic photoelectric conversion section 20 acquires a color signal of green (G). For example, the organic photoelectric conversion section 80 acquires a color signal of blue (B). For example, the inorganic photoelectric conversion section 32 acquires a color signal of red (R). This enables the imaging element 10B to acquire a plurality of types of color signals in one pixel without using a color filter.

The organic photoelectric conversion sections 20 and 80 have a configuration similar to that of the imaging element 10A of the foregoing second embodiment, for example. Specifically, in the organic photoelectric conversion section 20, the lower electrode 21, the insulating layer 22, the charge accumulation layer 23, the photoelectric conversion layer 24, the work function adjustment layer 25, the electron injection promoting layer 27, and the upper electrode 26 are stacked in this order, in the same manner as the imaging element 10A. The lower electrode 21 includes a plurality of electrodes (e.g., the readout electrode 21A and the accumulation electrode 21B). The readout electrode 21A of the lower electrode 21 is electrically coupled to the charge accumulation layer 23 via the opening 22H provided in the insulating layer 22. Also in the organic photoelectric conversion section 80, there are stacked a lower electrode 81, an insulating layer 82, a charge accumulation layer 83, a photoelectric conversion layer 84, a work function adjustment layer 85, an electron injection promoting layer 87, and an upper electrode 86 in this order, in the same manner as the organic photoelectric conversion section 20. The lower electrode 81 includes a plurality of electrodes (e.g., a readout electrode 81A and an accumulation electrode 81B). The readout electrode 81A of the lower electrode 81 is electrically coupled to the charge accumulation layer 83 via an opening 82H provided in the insulating layer 82. It is to be noted that the organic photoelectric conversion sections 20 and 80 may each have a configuration similar to that of the imaging element 10 of the foregoing first embodiment, and the electron injection promoting layers 27 and 87 may be omitted.

A through-electrode 91 is coupled to the readout electrode 81A. The through-electrode 91 penetrates an interlayer insulating layer 89 and the organic photoelectric conversion section 20, and is electrically coupled to the readout electrode 21A of the organic photoelectric conversion section 20. Further, the readout electrode 81A is electrically coupled to a floating diffusion FD provided in the semiconductor substrate 30 via through-electrodes 34 and 91, thus enabling electric charge generated in the photoelectric conversion layer 84 to be temporarily accumulated. Further, the readout electrode 81A is electrically coupled to the amplifier transistor AMP or the like provided in the semiconductor substrate 30 via the through-electrodes 34 and 91.

### 3-2. Modification Example 2

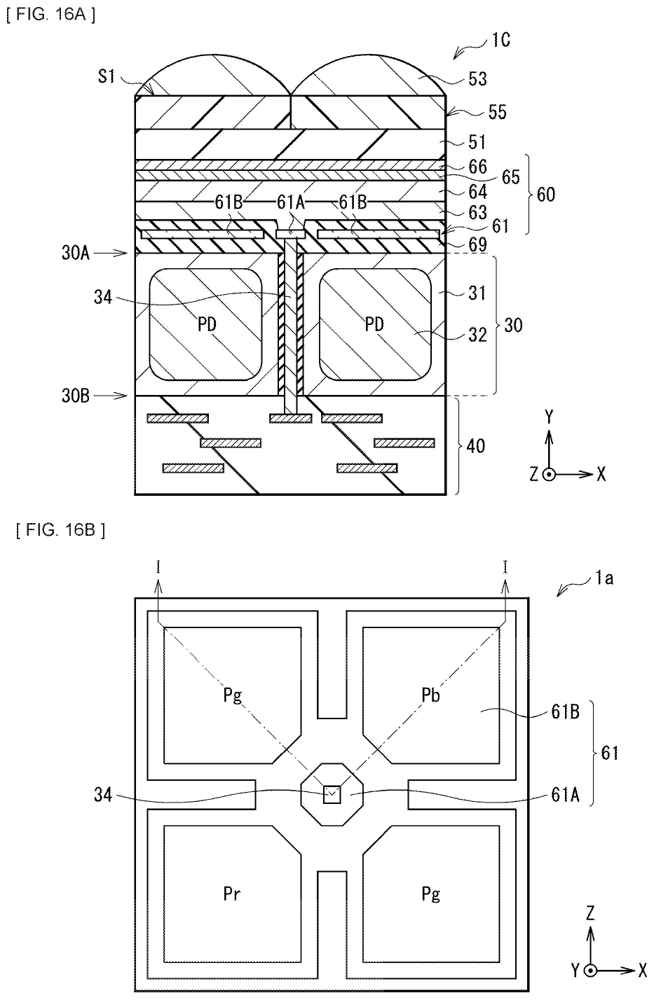

FIG. 16A schematically illustrates a cross-sectional configuration of an imaging element 10C according to Modification Example 2 of the present disclosure. FIG. 16B schematically illustrates an example of a planar configuration of the imaging element 10C illustrated in FIG. 16A, and FIG. 16A illustrates a cross-section along a line I-I illustrated in FIG. 16B. The imaging element 10C is, for example, a stacked imaging element in which the inorganic photoelectric conversion section 32 and the organic photoelectric conversion section 60 are stacked. In the pixel section 100A of the imaging device (e.g., imaging device 1) including the imaging element 10C, the pixel unit 1a including four pixels arranged in two rows×two columns is a repeating unit, for example, as illustrated in FIG. 16B, and the pixel units 1a are repeatedly arranged in array in a row direction and a column direction.

The imaging element 10C of the present modification example is provided with color filters 55 above the organic photoelectric conversion section 60 (light incident side S1) for the respective unit pixels P. The respective color filters 55 selectively transmit red light (R), green light (G), and blue light (B). Specifically, in the pixel unit 1a including the four pixels arranged in two rows×two columns, two color filters each of which selectively transmits green light (G) are disposed on a diagonal line, and color filters that selectively transmit red light (R) and blue light (B) are arranged one by one on the orthogonal diagonal line. Unit pixels (Pr, Pg, and Pb) provided with the respective color filters each detect the corresponding color light, for example, in the organic photoelectric conversion section 60. In other words, the respective pixels (Pr, Pg, and Pb) that detect red light (R), green light (G), and blue light (B) have a Bayer arrangement in the pixel section 100A.

The organic photoelectric conversion section 60 absorbs light corresponding to a portion or all of a wavelength of a visible light region of 400 nm or more and less than 750 nm, for example, to generate excitons (electron-hole pairs). In the organic photoelectric conversion section 60, there are stacked a lower electrode 61, an insulating layer (an interlayer insulating layer 69), a charge accumulation layer 63, a photoelectric conversion layer 64, a work function adjustment layer 65, and an upper electrode 66 in this order. The lower electrode 61, the interlayer insulating layer 69, the charge accumulation layer 63, the photoelectric conversion layer 64, the work function adjustment layer 65, and the upper electrode 66 respectively have configurations similar to those of the lower electrode 21, the insulating layer 22, the charge accumulation layer 23, photoelectric conversion layer 24, the work function adjustment layer 25, and the upper electrode 26 of the imaging element 10 in the foregoing first embodiment. The lower electrode 61 includes, for example, a readout electrode 61A and an accumulation electrode 61B independent of each other, and the readout electrode 61A is shared by four pixels, for example.

The inorganic photoelectric conversion section 32 detects an infrared light region of 750 nm or more and 1300 nm or less, for example.

In the imaging element 10C, light beams (red light (R), green light (G), and blue light (B)) of the visible light region, among the light beams transmitted through the color filters 55, are absorbed by the respective organic photoelectric conversion sections 60 of the unit pixels (Pr, Pg, and Pb) provided with the respective color filters. The other light, e.g., light (infrared light (IR)) in the infrared light region (e.g., 750 nm or more and 1000 nm or less) is transmitted through the organic photoelectric conversion section 60. This infrared light (IR) transmitted through the organic photoelectric conversion section 60 is detected by the inorganic photoelectric conversion section 32 of each of the unit pixels Pr, Pg, and Pb. Each of the unit pixels Pr, Pg, and Pb generates signal charge corresponding to the infrared light (IR). In other words, the imaging device 1 including the imaging element 10C is able to simultaneously generate both a visible light image and an infrared light image.

In addition, in the imaging device 1 provided with the imaging element 10C is able to acquire the visible light image and the infrared light image at the same position in an X-Z in-plane direction. It is therefore possible to achieve higher integration in the X-Z in-plane direction.

### 2-3. Modification Example 3

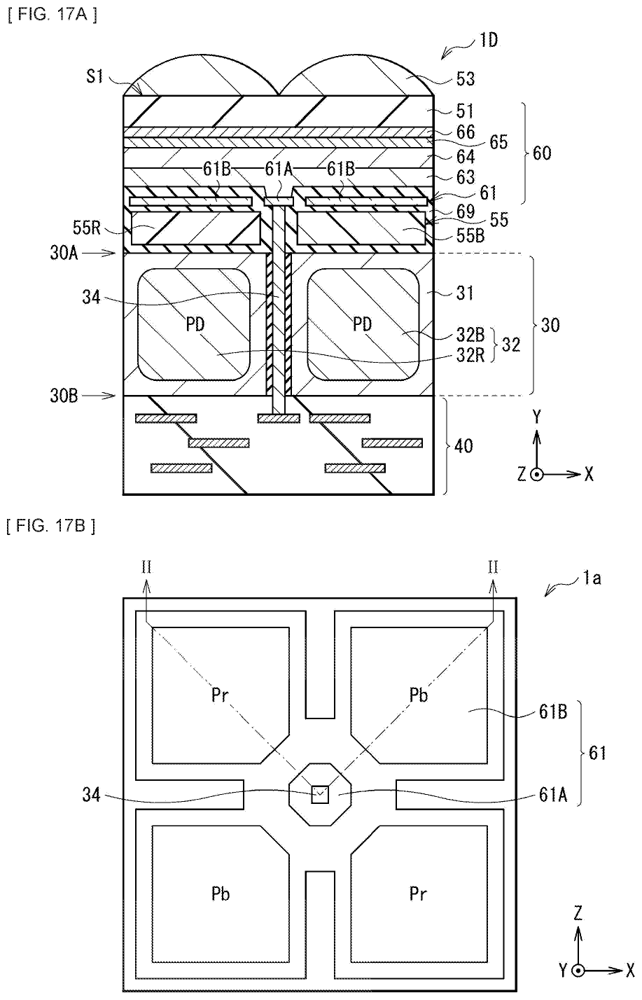

FIG. 17A schematically illustrates a cross-sectional configuration of an imaging element 10D of Modification Example 3 of the present disclosure. FIG. 17B schematically illustrates an example of a planar configuration of the imaging element 10D illustrated in FIG. 17A. FIG. 17A illustrates a cross-section along a line II-II illustrated in FIG. 17B. In the foregoing Modification Example 2, the example has been described in which the color filters 55 are provided above the organic photoelectric conversion section 60 (light incident side S1), but the color filter 55 may be provided between the inorganic photoelectric conversion section 32 and the organic photoelectric conversion section 60, for example, as illustrated in FIG. 17A.

For example, the imaging element 10D have a configuration in which color filters (color filters 55R) each of which selectively transmits at least red light (R) and color filters (color filters 55B) each of which selectively transmits at least blue light (B) are arranged on the respective diagonal lines in the pixel unit 1a. The organic photoelectric conversion section 60 (photoelectric conversion layer 64) is configured to selectively absorb light having a wavelength corresponding to green light (G), for example. The inorganic photoelectric conversion section 32R selectively absorbs light having a wavelength corresponding to red light (R), and the inorganic photoelectric conversion section 32B selectively absorbs light having a wavelength corresponding to blue light (B). This enables the organic photoelectric conversion sections 60 and the respective inorganic photoelectric conversion sections 32 (inorganic photoelectric conversion sections 32R and 32B) arranged below the color filters 55R and 55B to acquire signals corresponding to red light (R), green light (G), or blue light (B). The imaging element 10D according to the present modification example enables the respective photoelectric conversion sections of R, G, and B to each have larger area than that of the photoelectric conversion element having a typical Bayer arrangement. This makes it possible to improve the S/N ratio.

It is to be noted that the foregoing Modification Examples 2 and 3 each exemplify the organic photoelectric conversion section 60 in which the lower electrode 61, an insulating layer 62, the charge accumulation layer 63, the photoelectric conversion layer 64, the work function adjustment layer 65, and the upper electrode 66 are stacked in this order; however, this is not limitative. In the same manner as the foregoing second embodiment, each of the organic photoelectric conversion sections 60 may be provided with an electron injection layer between the work function adjustment layer 65 and the upper electrode 66.

### 2-4. Modification Example 4

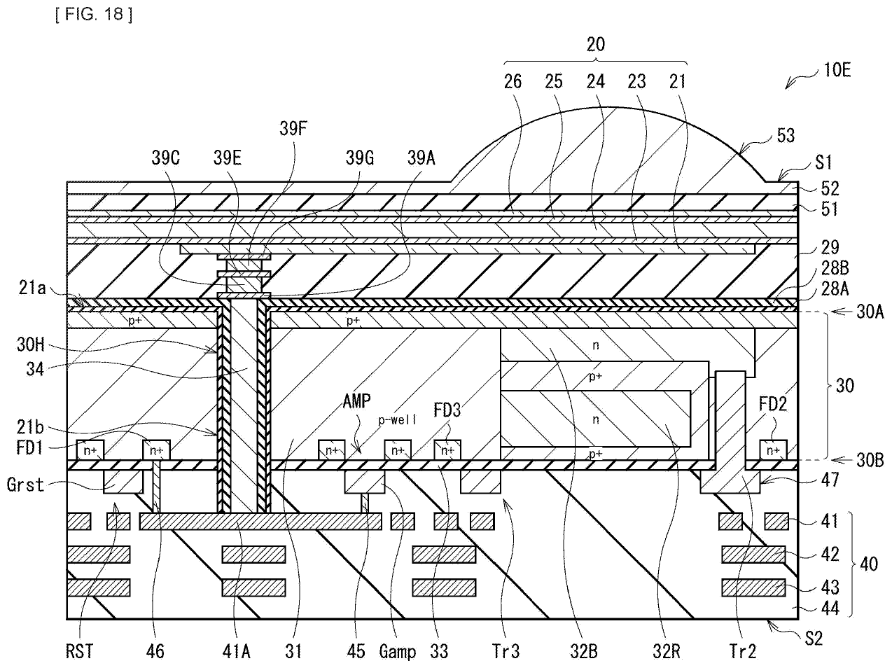

FIG. 18 schematically illustrates a cross-sectional configuration of an imaging element 10E according to Modification Example 4 of the present disclosure. The imaging element 10E of the present modification example is a modification example of the foregoing first embodiment, and differs from the foregoing first embodiment and the like in that the lower electrode 21 includes one electrode for each of the unit pixels P.

In the imaging element 10E, one organic photoelectric conversion section 20 and two inorganic photoelectric conversion sections 32B and 32R are stacked in the vertical direction for each of the unit pixels P, in the same manner as the above-described imaging element 10. The organic photoelectric conversion section 20 is provided on the side of the first surface 30A of the semiconductor substrate 30. The inorganic photoelectric conversion sections 32B and 32R are formed to be embedded in the semiconductor substrate 30, and are stacked in the thickness direction of the semiconductor substrate 30.

The imaging element 10E of the present modification example has a configuration similar to that of the above-described imaging element 10 except that the lower electrode 21 of the organic photoelectric conversion section 20 includes one electrode and that the insulating layer 22 and the charge accumulation layer 23 are not provided between the lower electrode 21 and the photoelectric conversion layer 24, as described above.

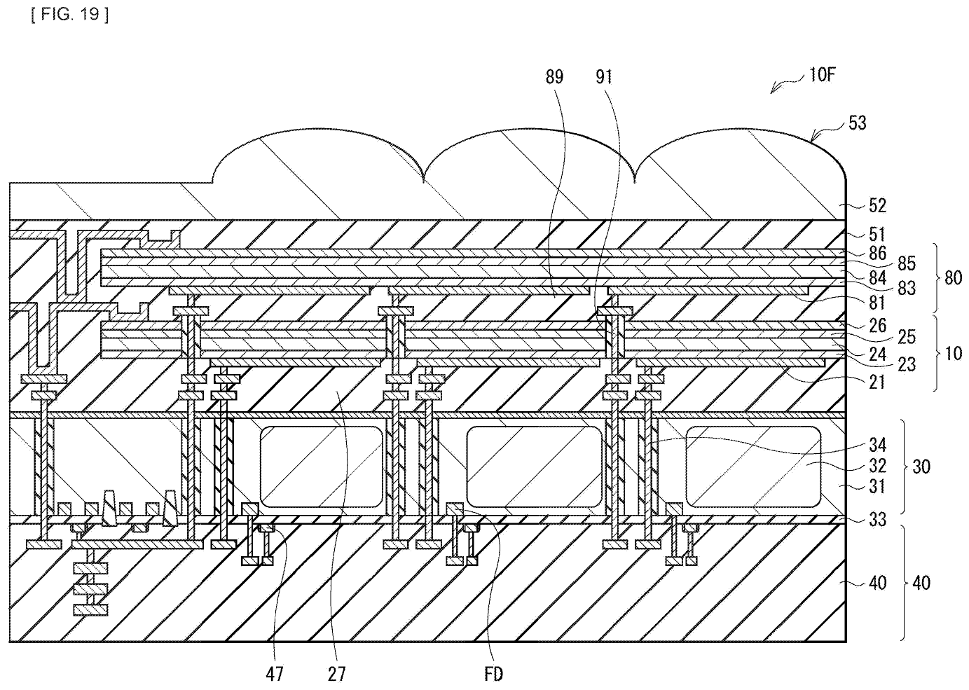

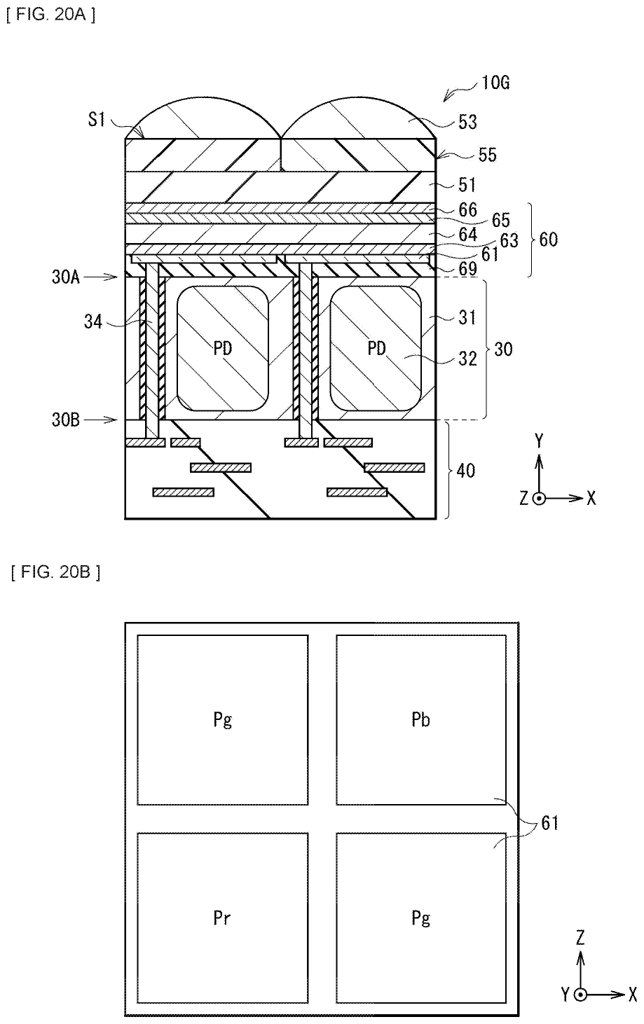

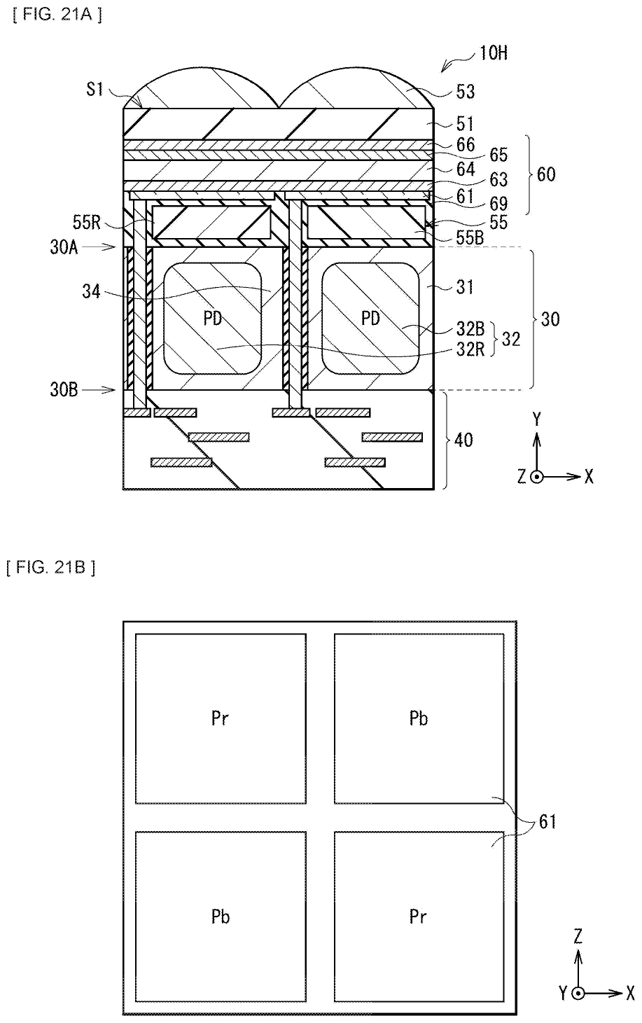

FIG. 19 schematically illustrates a cross-sectional configuration of an imaging element 10F according to Modification Example 4 of the present disclosure. FIG. 20A schematically illustrates a cross-sectional configuration of an imaging element 10G according to Modification Example 4 of the present disclosure. FIG. 20B schematically illustrates an example of a planar configuration of the imaging element 10G illustrated in FIG. 20A. FIG. 21A schematically illustrates a cross-sectional configuration of an imaging element 10H according to Modification Example 4 of the present disclosure. FIG. 21B schematically illustrates an example of a planar configuration of the imaging element 10H illustrated in FIG. 21A. The imaging elements 10F to 10H are respective modification examples of the foregoing Modification Examples 1 to 3, and the lower electrode (e.g., lower electrode 21) includes one electrode for each of the unit pixels P, in the same manner as the above-described imaging element 10E. The imaging elements 10F to 10H have configurations similar to those of the corresponding imaging element 10B to 10D of Modification Examples 1 to 3 except that the insulating layer (e.g., insulating layer 22) and the charge accumulation layer (e.g., the charge accumulation layer 23) are not provided between the lower electrode (e.g., lower electrode 21) and the photoelectric conversion layer (e.g., photoelectric conversion layer 24).

As described above, the foregoing first embodiment and Modification Examples 1 to 3 exemplify the cases where the lower electrodes 21, 61, and 81 constituting the organic photoelectric conversion sections 20, 60, and 80 respectively include a plurality of electrodes (readout electrodes 21A, 61A, and 81A and accumulation electrodes 21B, 61B, and 81B); however, this is not limitative. The imaging elements 10, 10B, 10C, and 10D according to the foregoing first embodiment and Modification Examples 1 to 3 are also applicable to a case where the lower electrode includes one electrode for each of the unit pixels P, thus making it possible to obtain effects similar to those of the foregoing first embodiment and the like.

It is to be noted that the present modification example exemplifies the organic photoelectric conversion sections 20, 60, and 80 in which the lower electrodes 21, 61, and 81, the photoelectric conversion layers 24, 64, and 84, the work function adjustment layers 25, 65, and 85, and the upper electrodes 26, 66, and 86 are respectively stacked in this order, but this is not limitative. In the same manner as the foregoing second embodiment, the organic photoelectric conversion sections 20, 60, and 80 may be respectively provided with electron injection layers between the work function adjustment layers 25, 65, and 85 and the upper electrodes 26, 66, and 86.

### 4. Application Examples

### Application Example 1

FIG. 22 illustrates an example of an overall configuration of an imaging device (imaging device 1) including the imaging element (e.g., imaging element 10) illustrated in FIG. 1 or other drawings.

The imaging device 1 is, for example, a CMOS image sensor. The imaging device 1 takes in incident light (image light) from a subject via an optical lens system (unillustrated), and converts the amount of incident light formed on an imaging surface as an image into electric signals in units of pixels to output the electric signals as pixel signals. The imaging device 1 includes the pixel section 100A as an imaging area on the semiconductor substrate 30. In addition, the imaging device 1 includes, for example, the vertical drive circuit 111, a column signal processing circuit 112, the horizontal drive circuit 113, an output circuit 114, a control circuit 115, and an input/output terminal 116 in a peripheral region of this pixel section 100A.

The pixel section 100A includes, for example, the plurality of unit pixels P that are two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the pixels. One end of the pixel drive line Lread is coupled to an output terminal of the vertical drive circuit 111 corresponding to each of the rows.

The vertical drive circuit 111 is a pixel drive section that is configured by a shift register, an address decoder, and the like and drives the unit pixels P of the pixel section 100A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the imaging device 1. The control circuit 115 further includes a timing generator that generates various timing signals, and controls driving of the peripheral circuits including the vertical drive circuit 111, the column signal processing circuit 112, the horizontal drive circuit 113, and the like on the basis of the various timing signals generated by the timing generator.

The input/output terminal 116 exchanges signals with the outside.

### Application Example 2

In addition, the above-described imaging device 1 is applicable, for example, to various types of electronic apparatuses with an imaging function including an imaging system such as a digital still camera and a video camera, a mobile phone having an imaging function, or another device having an imaging function.

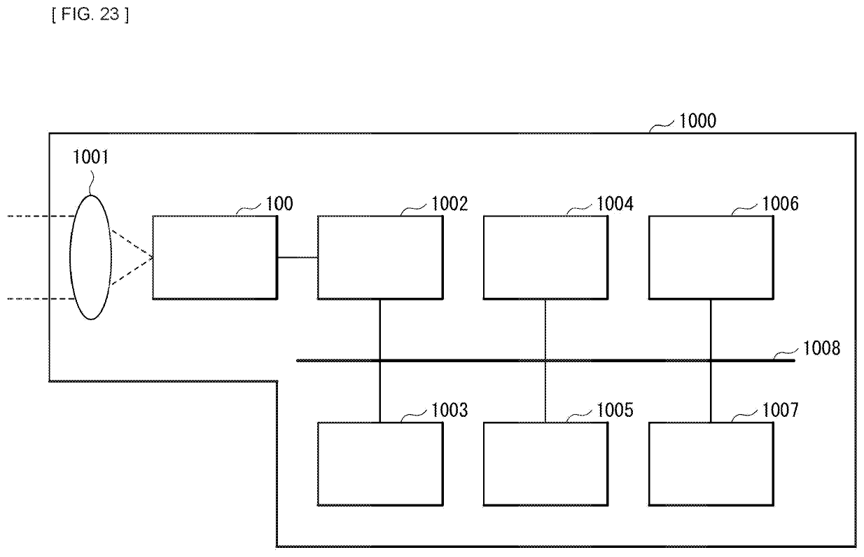

FIG. 23 is a block diagram illustrating an example of a configuration of an electronic apparatus 1000.

As illustrated in FIG. 23, the electronic apparatus 1000 includes an optical system 1001, the imaging device 1, and a DSP (Digital Signal Processor) 1002, and has a configuration in which the DSP 1002, a memory 1003, a display device 1004, a recording device 1005, an operation system 1006, and a power supply system 1007 are coupled together via a bus 1008, thus making it possible to capture a still image and a moving image.

The optical system 1001 includes one or a plurality of lenses, and takes in incident light (image light) from a subject to form an image on an imaging surface of the imaging device 1.

The above-described imaging device 1 is applied as the imaging device 1. The imaging device 1 converts the amount of incident light formed as an image on the imaging surface by the optical system 1001 into electric signals in units of pixels, and supplies the DSP 1002 with the electric signals as pixel signals.

The DSP 1002 performs various types of signal processing on the signals from the imaging device 1 to acquire an image, and causes the memory 1003 to temporarily store data on the image. The image data stored in the memory 1003 is recorded in the recording device 1005, or is supplied to the display device 1004 to display the image. In addition, the operation system 1006 receives various operations by the user, and supplies operation signals to the respective blocks of the electronic apparatus 1000. The power supply system 1007 supplies electric power required to drive the respective blocks of the electronic apparatus 1000.

### Application Example 3

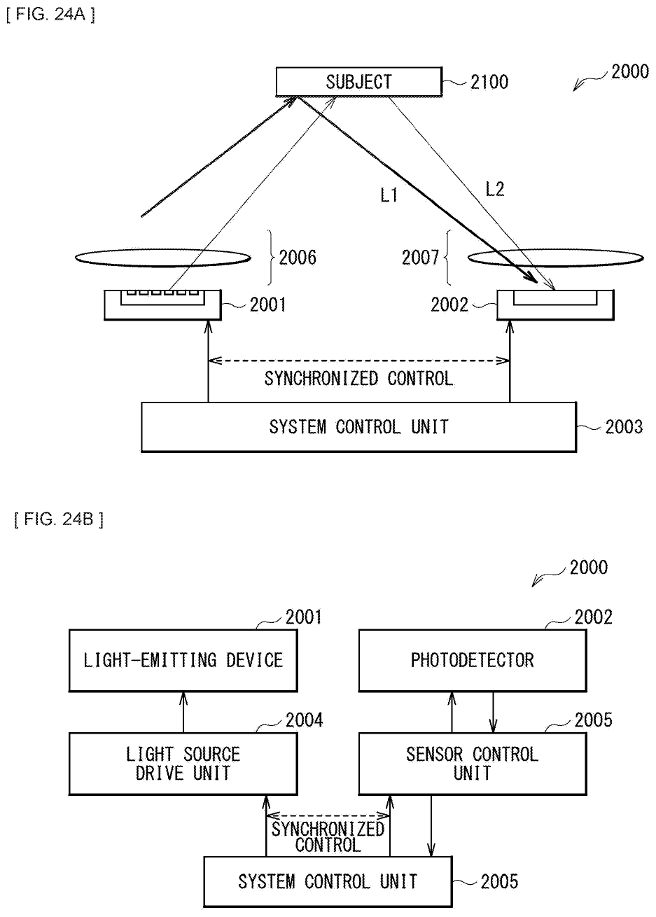

FIG. 24A schematically illustrates an example of an overall configuration of a photodetection system 2000 including the imaging device 1. FIG. 24B illustrates an example of a circuit configuration of the photodetection system 2000. The photodetection system 2000 includes a light-emitting device 2001 as a light source unit that emits infrared light L2 and a photodetector 2002 as a light-receiving unit with a photoelectric conversion element. The above-described imaging device 1 can be used as the photodetector 2002. The photodetection system 2000 may further include a system control unit 2003, a light source drive unit 2004, a sensor control unit 2005, a light source side optical system 2006, and a camera side optical system 2007.

The photodetector 2002 is able to detect light L1 and light L2. The light L1 is reflected light of ambient light from the outside reflected by a subject (measurement target) 2100 (FIG. 24A). The light L2 is light reflected by the subject 2100 after having been emitted by the light-emitting device 2001. The light L1 is, for example, visible light, and the light L2 is, for example, infrared light. The light L1 is detectable at the photoelectric conversion section in the photodetector 2002, and the light L2 is detectable at a photoelectric conversion region in the photodetector 2002. It is possible to acquire image information on the subject 2100 from the light L1 and to acquire information on a distance between the subject 2100 and the photodetection system 2000 from the light L2. For example, the photodetection system 2000 can be mounted on an electronic apparatus such as a smartphone or on a mobile body such as a car. The light-emitting device 2001 can be configured by, for example, a semiconductor laser, a surface-emitting semiconductor laser, or a vertical resonator surface-emitting laser (VCSEL). An iTOF method can be employed as a method for the photodetector 2002 to detect the light L2 emitted from the light-emitting device 2001; however, this is not limitative. In the iTOF method, the photoelectric conversion section is able to measure a distance to the subject 2100 by time of flight of light (Time-of-Flight; TOF), for example. As a method for the photodetector 2002 to detect the light L2 emitted from the light-emitting device 2001, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject. It is to be noted that it is possible for the system control unit 2003 to synchronously control the light-emitting device 2001 and the photodetector 2002.

### 5. Practical Application Examples

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

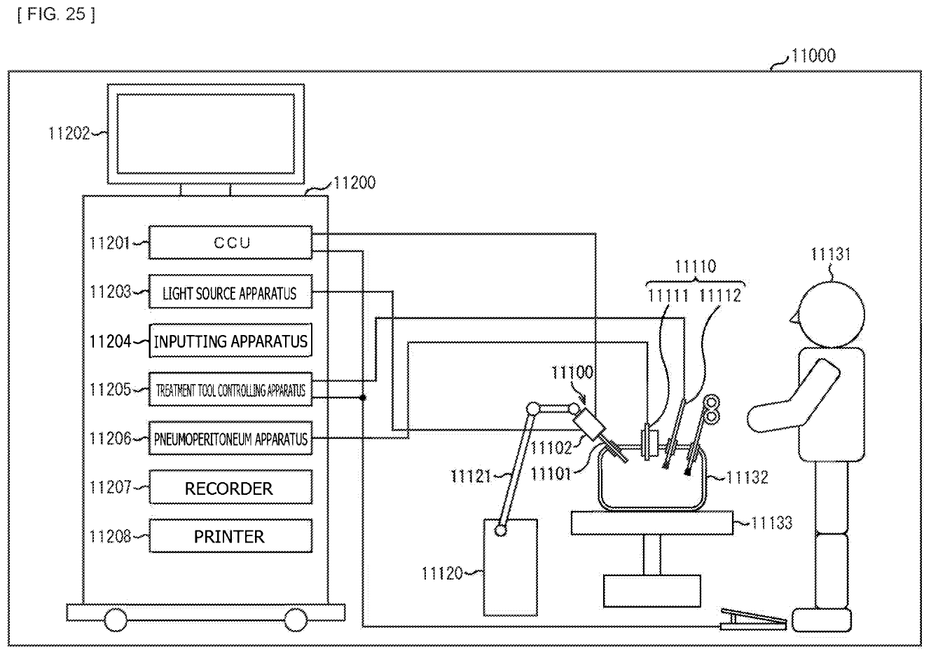

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

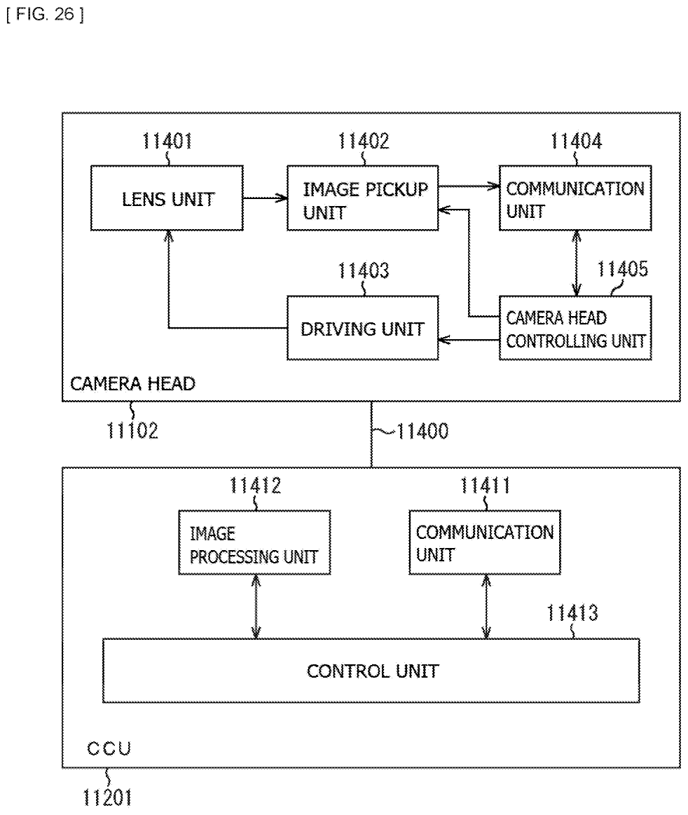

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

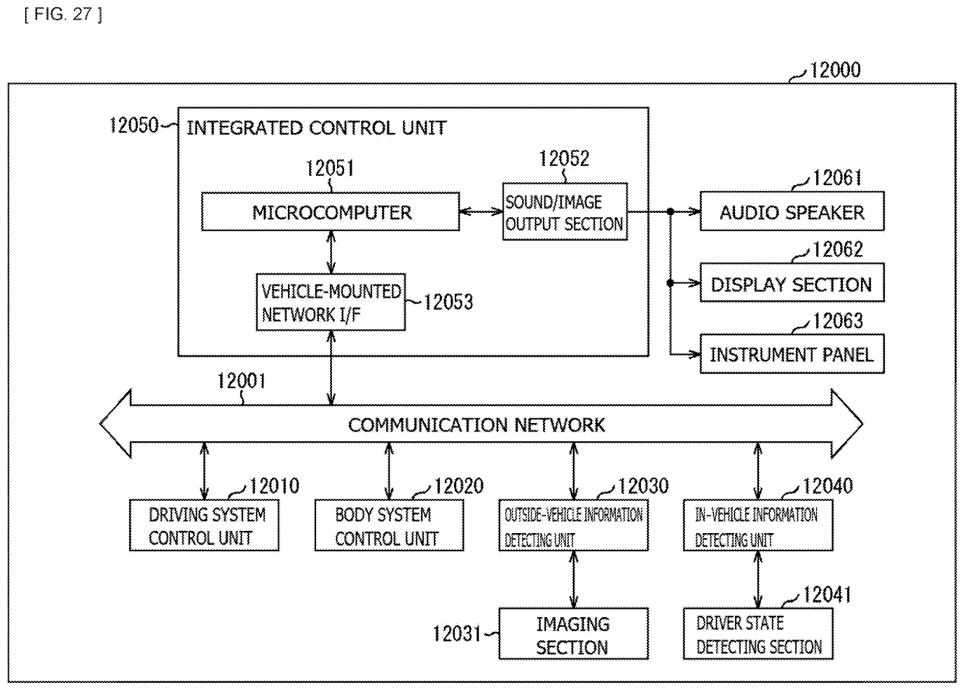

FIG. 27 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

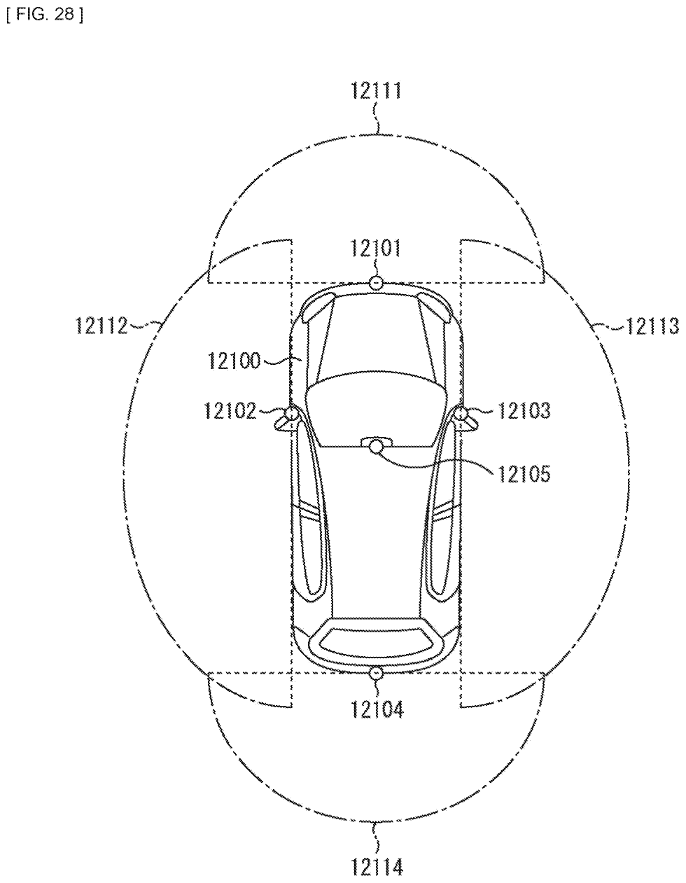

FIG. 28 is a diagram depicting an example of the installation position of the imaging section 12031.

In FIG. 28, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 28 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the imaging element (e.g., imaging element 10) according to any of the foregoing embodiments and modification examples thereof is applicable to the imaging section 12031. The application of the technology according to an embodiment of the present disclosure to the imaging section 12031 allows for a high-definition captured image with less noise, thus making it possible to perform highly accurate control utilizing the captured image in the mobile body control system.

### 6. Examples

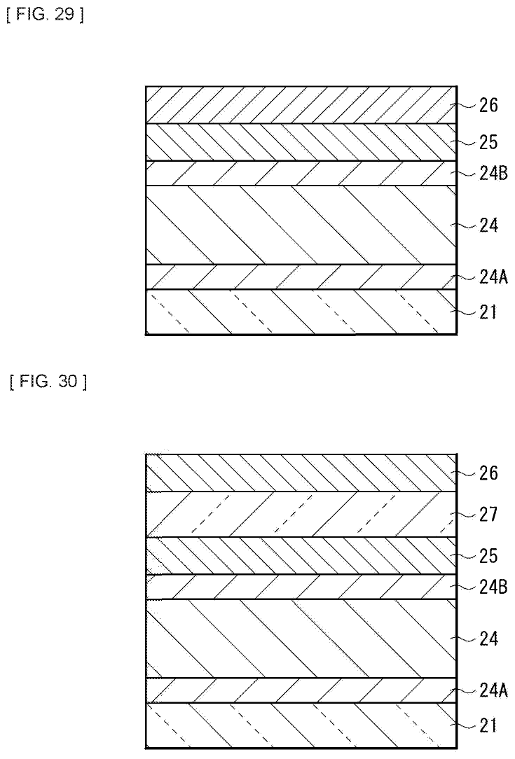

Next, description is given in detail of Examples of the present disclosure. In the following, imaging elements having cross-sectional configurations illustrated in FIG. 29 (Experiment 1) and FIG. 30 (Experiment 2) were fabricated, as device samples, and characteristics of the devices were evaluated.

### Experiment 1

### Experimental Example 1-1

An ITO film having a thickness of 100 nm was formed on a silicon substrate using a sputtering apparatus. The ITO film was patterned by photolithography and etching to form an ITO electrode (lower electrode 21). Subsequently, a silicon substrate provided with the ITO electrode was washed by UV/ozone processing. Thereafter, the silicon substrate was moved to a vacuum-deposition machine, and organic layers were stacked in order on the silicon substrate while rotating a substrate holder in a depressurized state of 1×10⁻⁵ Pa or less. First, F6-OPh-26F2 represented by the following formula (1) and fullerene C₆₀ represented by the following formula (2) were deposited at a substrate temperature of 52° C. and at film formation rates of 1.0 Å/sec and 0.25 Å/sec, respectively, to allow a mixed layer to have a thickness of 10 nm, thus forming a hole blocking layer 24A. Next, F6-OPh-26F2, DPh-BTBT represented by the following formula (3), and fullerene C₆₀ were deposited at a substrate temperature of 52° C. and at film formation rates of 0.50 Å/sec, 0.50 Å/sec, and 0.25 Å/sec, respectively, to allow a mixed layer to have a thickness of 230 nm, thus forming the photoelectric conversion layer 24. Subsequently, CzBDF represented by the following formula (4) was deposited at a substrate temperature of 52° C. to have a thickness of 10 nm, thus forming an electron blocking layer 24B. Next, HATCN represented by the following formula (5) and fullerene C₆₀ were deposited at a substrate temperature of 0° C. and at film formation rates of 1.4 Å/sec and 0.64 Å/sec, respectively, to allow a mixed layer to have a thickness of 10 nm, thus forming the work function adjustment layer 25. Finally, the silicon substrate was moved to the sputtering apparatus, and an ITO film was deposited on the work function adjustment layer 25 to have a thickness of 50 nm, thus forming the upper electrode 26. Through the above-described fabrication method, a sample (Experimental Example 1-1) having a photoelectric conversion region of 1 mm×1 mm was fabricated. The fabricated device sample was subjected to annealing treatment at 150° C. for 210 minutes in a nitrogen (N₂) atmosphere.

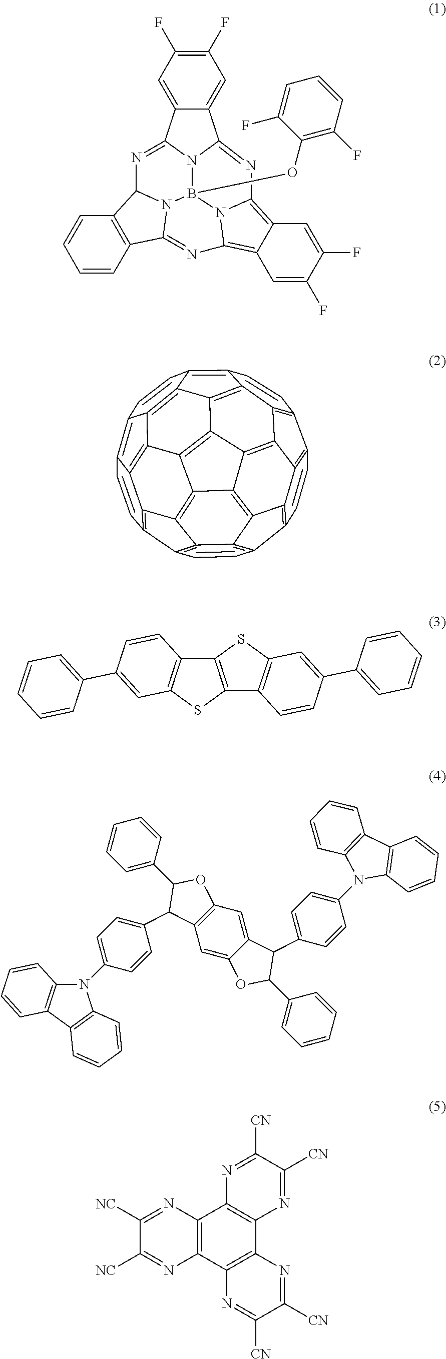

### Experimental Example 1-2

In Experimental Example 1-2, a device sample (Experimental Example 1-2) was fabricated using a method similar to that of Experimental Example 1-1, except that HATCN and fullerene Coo were deposited at film formation rates of 1.0 Å/sec and 1.0 Å/sec, respectively, to form the work function adjustment layer 25.

### Experimental Example 1-3

In Experimental Example 1-3, a device sample (Experimental Example 1-3) was fabricated using a method similar to that of Experimental Example 1-1, except that HATCN and fullerene C₆₀ were deposited at film formation rates of 0.6 Å/sec and 1.4 Å/sec, respectively, to form the work function adjustment layer 25.

### Experimental Example 1-4

In Experimental Example 1-4, a device sample (Experimental Example 1-4) was fabricated using a method similar to that of Experimental Example 1-3, except that fullerene C₇₀ represented by the following formula (6) was used instead of fullerene Coo to form the work function adjustment layer 25.

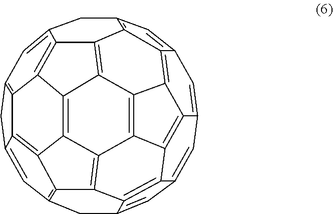 [SMILES: c1c2c3c4c(cc5c6c4c4c7c3c3c1Cc1cc8cc9cc%10cc(c%11c%10c%10c9c9c8c1c3c7c9c%10c4c%116)C5)C2]

### Experimental Example 1-5

In Experimental Example 1-5, a device sample (Experimental Example 1-5) was fabricated using a method similar to that of Experimental Example 1-3, except that HATCN, fullerene C₆₀, and NDI-35 represented by the following formula (7) were deposited at film formation rates of 0.6 Å/sec, 0.2 Å/sec, and 1.4 Å/sec, respectively, to form the work function adjustment layer 25.

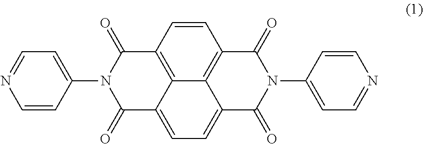 [SMILES: O=C1c2ccc3c4c(ccc(c24)C(=O)N1c1ccncc1)C(=O)N(c1ccncc1)C3=O]

### Experimental Example 1-6

In Experimental Example 1-6, a device sample (Experimental Example 1-6) was fabricated using a method similar to that of Experimental Example 1-1, except that the work function adjustment layer 25 was formed only using HATCN.

### Experimental Example 1-7

In Experimental Example 1-7, a device sample (Experimental Example 1-7) was fabricated using a method similar to that of Experimental Example 1-1, except that fullerene C₆₀ was changed to NBphen represented by the following formula (8) to form the work function adjustment layer 25.

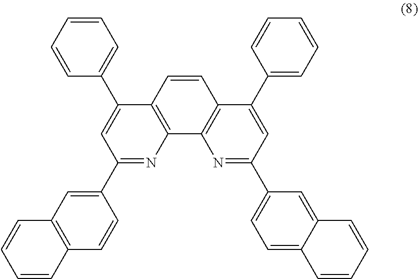 [SMILES: c1ccc(-c2cc(-c3ccc4ccccc4c3)nc3c2ccc2c(-c4ccccc4)cc(-c4ccc5ccccc5c4)nc23)cc1]

### Experimental Example 1-8

In Experimental Example 1-8, a device sample (Experimental Example 1-8) was fabricated using a method similar to that of Experimental Example 1-3, except that HATCN was changed to F6-TCNNQ represented by the following formula (9) to form the work function adjustment layer 25.

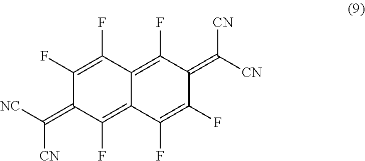 [SMILES: N#CC(C#N)=c1c(F)c(F)c2c(F)c(=C(C#N)C#N)c(F)c(F)c2c1F]

### Experimental Example 1-9

In Experimental Example 1-9, a device sample (Experimental Example 1-9) was fabricated using a method similar to that of Experimental Example 1-8, except that F6-TCNNQ and fullerene C₆₀ were deposited at film formation rates of 0.2 Å/sec and 1.8 Å/sec, respectively, to form the work function adjustment layer 25.

### Experimental Example 1-10

In Experimental Example 1-10, a device sample (Experimental Example 1-10) was fabricated using a method similar to that of Experimental Example 1-8, except that the work function adjustment layer 25 was formed only using F6-TCNNQ.

The following evaluation methods were used to evaluate a dark current, EQE, a response speed, and aggregation, adhesive force and yield in the work function adjustment layer 25, etc. in each of device samples in the foregoing Experimental Examples 1-1 to 1-10, and results thereof were summarized in Table 1. It is to be noted that, as for the dark current and the response time exhibited in Table 1, the characteristic value of Experimental Example 1-1 was standardized as one to perform relative comparison.

### (Evaluation of Dark Current and EQE)

A wavelength of light irradiated to an imaging element via a band-pass filter from a green LED light source was set to 560 nm, and an amount of the light was set to 162 ρW/cm². A vias voltage to be applied between electrodes of the device sample was controlled using a semiconductor parameter analyzer, and a voltage to be applied to the lower electrode 21 was swept with respect to the upper electrode 26, to thereby obtain a current-voltage curve. A dark current value and a light current value at a reverse bias application state (a state of a voltage of +2.6 V being applied) were acquired, and a value obtained by subtracting the dark current value from the light current value was converted into the number of electrons, followed by division by the number of incident photons, thereby calculating EQE.

### (Evaluation of Response Speed)

A wavelength of light irradiated to the device sample via a band-pass filter from a green LED light source was set to 560 nm, and an amount of the light was set to 162 μW/cm². A voltage to be applied to an LED driver was controlled by a function generator, and pulse light was irradiated from a side of the upper electrode 26 of the device sample. Pulse light was irradiated in such a state that a bias voltage to be applied between electrodes of the device sample was applied to the lower electrode 21 at a voltage of +2.6 V with respect to the upper electrode 26, and then a current attenuation waveform was observed using an oscilloscope. A coulomb amount in the process of current attenuation was measured 110 ms after the timing immediately after the irradiation of the light pulse. This coulomb amount was defined as the response time, and was set as an index of the response speed.

### (Evaluation of Other Indexes)

As for the aggregation, an atomic force microscope (AFM) was used to determine a film having an arithmetic mean roughness (Ra) of 0.8 nm or less to have no aggregation (A), and a film having an arithmetic mean roughness (Ra) greater than 0.8 nm to have aggregation (B). As for adhesiveness, a surface-interface cutting method (SAICAS method) was used to determine a case of the detachment intensity being 0.05 KN/m or more to be A, and a case of being less than 0.05 KN/m to be B. As for the yield, a dark current measurement was used to set a yield of 80% or more to be A, and a yield of less than 80% to be B. As for the electron affinity, a sample in which an ITO film and a single film of each material to be measured are deposited on a quartz substrate was formed, and each energy level was determined by UPS and LEIPS.

TABLE 1

| | | | | Mixing | | Adhesive | | LUMO | Dark | Response |
|---|---|---|---|---|---|---|---|---|---|---|
| | WFT1 | WFT2 | WFT3 | Ratio | Aggregation | Force | Yield | [eV] | Current | Time |
| Experimental | Formula | Formula | — | 7 to 3 to 0 | A | A | A | 5.1 | 1.0 | 1.0 |
| Example 1-1 | (5) | (2) | | | | | | | | |
| Experimental | Formula | Formula | — | 5 to 5 to 0 | A | A | A | 5.0 | 1.1 | 0.97 |
| Example 1-2 | (5) | (2) | | | | | | | | |
| Experimental | Formula | Formula | — | 3 to 7 to 0 | A | A | A | 4.9 | 1.3 | 0.96 |
| Example 1-3 | (5) | (2) | | | | | | | | |
| Experimental | Formula | Formula | — | 3 to 7 to 0 | A | A | A | 4.9 | 1.4 | 0.97 |
| Example 1-4 | (5) | (3) | | | | | | | | |
| Experimental | Formula | Formula | Formula | 3 to 6 to 1 | A | A | A | 4.8 | 1.3 | 0.95 |
| Example 1-5 | (5) | (2) | (7) | | | | | | | |
| Experimental | Formula | — | — | — | B | B | B | 5.2 | 1.0 | 1.6 |
| Example 1-6 | (5) | | | | | | | | | |
| Experimental | Formula | Formula | — | 3 to 7 to 0 | A | A | B | 4.2 | 85 | — |
| Example 1-7 | (5) | (8) | | | | | | | | |
| Experimental | Formula | Formula | — | 3 to 7 to 0 | A | A | A | 5.5 | 1.0 | 1.0 |
| Example 1-8 | (9) | (2) | | | | | | | | |
| Experimental | Formula | Formula | — | 1 to 9 to 0 | A | A | A | 5.4 | 1.2 | 0.89 |
| Example 1-9 | (9) | (2) | | | | | | | | |
| Experimental | Formula | — | — | — | B | B | B | 5.8 | 0.98 | 1.6 |
| Example 1-10 | (9) | | | | | | | | | |

It was appreciated from Table 1 that Experimental Examples 1-1 to 1-5 each had no aggregation, high adhesive force, and excellent yield, thus obtaining results in which the dark current and the response speed were favorable. In contrast, as compared with Experimental Examples 1-1 to 1-5, Experimental Example 1-6 had aggregation, low adhesive force, and poor yield, thus causing the response speed to be deteriorated. One conceivable reason for this is that a monolayer film of HATCN was used as the work function adjustment layer 25 in Experimental Example 1-6. In addition, it is considered that the use of the monolayer film of HATCN as the work function adjustment layer 25 resulted in insufficient carrier conductivity at the interface between the electron blocking layer 24B and the work function adjustment layer 25, leading to an insufficient electric field to be applied to the photoelectric conversion layer 24, thus causing the response speed to be deteriorated. In Experimental Example 1-7, the dark current and the response speed were deteriorated, as compared with Experimental Examples 1-1 to 1-5. One conceivable reason for this is that a mixed film of HATCN and NBPhen, formed as the work function adjustment layer 25 in Experimental Example 1-7, has an electron affinity of 4.2 eV, thus exerting a large influence as a result of the injection of electrons into the photoelectric conversion layer from the work function adjustment layer, as compared with Experimental Examples 1-1 to 1-5.

Experimental Examples 1-8 to 1-9 each had no aggregation, high adhesive force, and excellent yield, thus obtaining results in which the dark current and the response speed were favorable. As compared with Experimental Examples 1-8 to 1-9, Experimental Example 1-10 had aggregation, low adhesive force, and poor yield, thus causing the response speed to be deteriorated. One conceivable reason for this is that a monolayer film of F6-TCNNQ was used as the work function adjustment layer 25 in Experimental Example 1-10. In addition, it is considered that the use of the monolayer film of F6-TCNNQ as the work function adjustment layer 25 resulted in insufficient carrier conductivity at the interface between the electron blocking layer 24B and the work function adjustment layer 25, leading to an insufficient electric field to be applied to the photoelectric conversion layer 24, thus causing the response speed to be deteriorated.

### Experiment 2

### Experimental Example 2-1

An ITO film having a thickness of 100 nm was formed on a silicon substrate using a sputtering apparatus. The ITO film was patterned by photolithography and etching to form an ITO electrode (lower electrode 21). Subsequently, a silicon substrate provided with the ITO electrode was washed by UV/ozone processing. Thereafter, the silicon substrate was moved to a vacuum-deposition machine, and organic layers were stacked in order on the silicon substrate while rotating a substrate holder in a depressurized state of 1×10⁻⁵ Pa or less. First, F6-OPh-26F2 represented by the formula (1) and fullerene C₆₀ represented by the formula (2) were deposited at a substrate temperature of 52° C. and at film formation rates of 1.0 Å/sec and 0.25 Å/sec, respectively, to allow a mixed layer to have a thickness of 10 nm, thus forming a hole blocking layer 24A. Next, F6-OPh-26F2, DPh-BTBT represented by the formula (3), and fullerene C₆₀ were deposited at a substrate temperature of 52° C. and at film formation rates of 0.50 Å/sec, 0.50 Å/sec, and 0.25 Å/sec, respectively, to allow a mixed layer to have a thickness of 230 nm, thus forming the photoelectric conversion layer 24. Subsequently, CzBDF represented by the formula (4) was deposited at a substrate temperature of 52° C. to allow have a thickness of 10 nm, thus forming an electron blocking layer 24B. Next, HATCN represented by the formula (5) and fullerene C₆₀ were deposited at a substrate temperature of 0° C. and at film formation rates of 1.4 Å/sec and 0.64 Å/sec, respectively, to allow a mixed layer to have a thickness of 10 nm, thus forming the work function adjustment layer 25. Subsequently, BBphen represented by the following formula (8) was deposited at a film formation rate of 0.3 Å/sec and at a thickness of 4 nm to form the electron injection promoting layer 27. Finally, the silicon substrate was moved to the sputtering apparatus, and an ITO film was deposited on the work function adjustment layer 25 to have a thickness of 50 nm, thus forming the upper electrode 26. Through the above-described fabrication method, a sample (Experimental Example 2-1) having a photoelectric conversion region of 1 mm×1 mm was fabricated. The fabricated device sample was subjected to annealing treatment at 150° C. for 210 minutes in a nitrogen (N₂) atmosphere.

### Experimental Example 2-2

In Experimental Example 2-2, a device sample (Experimental Example 2-2) was fabricated using a method similar to that of Experimental Example 2-1, except that the work function adjustment layer 25 was formed only using HATCN.

The above-described evaluation methods were used to evaluate a dark current, external quantum efficiency (EQE), and a response speed in each of device samples in the foregoing Experimental Examples 2-1 to 2-2, and results thereof were summarized in Table 2. It is to be noted that the characteristic value of Experimental Example 1-1 was standardized as one to perform relative comparison.

TABLE 2

| | | | Mixing | | Dark | | Response |
|---|---|---|---|---|---|---|---|
| | WFT1 | WFT2 | Ratio | EIL | Current | EQE | Time |
| Experimental | Formula | Formula | 7 to 3 | Formula | 1.0 | 1.05 | 0.85 |
| Example2-1 | (9) | (2) | | (8) | | | |
| Experimental | Formula | — | — | Formula | 12 | 0.87 | 4.3 |
| Example2-2 | (9) | | | (8) | | | |

Experimental Example 2-1 exhibited higher EQE and excellent response speed, as compared with Experimental Example 1-1. It is considered that, in Experimental Example 2-1, adopting a mixed film as the work function adjustment layer 25 increased the concentration of electrons in the work function adjustment layer 25 and improved the carrier conductivity at the interface between electron blocking layer 24B and the work function adjustment layer 25, as compared with Experimental Example 2-2, eventually making an electric field more likely to be applied to the photoelectric conversion layer 24, thus allowing higher EQE and excellent response speed to be obtained. In contrast, it was confirmed, in Experimental Example 2-2, that all of the dark current, the EQE and the response speed were deteriorated, as compared with Experimental Example 2-1. One conceivable reason for this is that, as compared with Experimental Example 2-1, Experimental Example 2-2 was provided with the electron injection promoting layer 27 including NBphen between the upper electrode 26 and the work function adjustment layer 25 having high aggregation and poor flatness, thus causing NBphen to enter a gap of a domain of the aggregated work function adjustment layer 25, which caused electrons to be directly injected into the photoelectric conversion layer 24. It is considered that this deteriorated the dark current, which accordingly deteriorated the EQE and the response speed. In other words, it was appreciated, in Experimental Example 2-1, that providing the electron injection promoting layer 27 on the highly flat work function adjustment layer 25 improved the element characteristic. In contrast, it was appreciated, in Experimental Example 2-2 including the work function adjustment layer 25 having high aggregation and low flatness, that, even when the electron injection promoting layer 27 was provided, no improved results were obtained, even as compared with Experimental Example 1-6.

Description has been given hereinabove referring to the first and second embodiments, Modification Examples 1 to 4 and Examples as well as the application example and the practical application examples; however, the content of the present disclosure is not limited to the foregoing embodiment and the like, and may be modified in a wide variety of ways. For example, in the foregoing first embodiment, the imaging element 10 has a configuration in which the organic photoelectric conversion section 20 that detects green light, and the inorganic photoelectric conversion sections 32B and 32R that detect, respectively, blue light and red light are stacked. However, the content of the present disclosure is not limited to such a structure. In other words, red light or blue light may be detected in the organic photoelectric conversion section, or green light may be detected in the inorganic photoelectric conversion section.

In addition, the numbers of the organic photoelectric conversion section and the inorganic photoelectric conversion section, and the ratio therebetween are not limitative. As in Modification Example 1, two or more organic photoelectric conversion sections may be provided, or color signals of multiple colors may be obtained only by the organic photoelectric conversion sections.

Further, the foregoing embodiments and the like exemplify the configuration in which two electrodes of the readout electrode 21A and the accumulation electrode 21B are used as the plurality of electrodes constituting the lower electrode 21. However, three or four or more electrodes such as transfer electrodes or discharge electrodes may be provided in addition thereto.

Furthermore, the foregoing embodiments and the like exemplify the lower electrode 21 being formed by using a plurality of electrodes. However, it is possible for the present technology to obtain similar effects also in an imaging element including a lower electrode that includes one electrode.

It is to be noted that the effects described herein are merely exemplary and are not limitative, and may further include other effects.

It is to be noted that the present disclosure may also have the following configurations. According to the present technology of the following configurations, a first semiconductor layer is provided between an organic layer at least including a photoelectric conversion layer and a second electrode. The first semiconductor layer has an electron affinity of 4.5 eV or more and 6.0 eV or less, and includes a first carbon-containing compound and a second carbon-containing compound. The first carbon-containing compound has an electron affinity greater than 4.8 eV or an electron affinity greater than a work function of the second electrode. The second carbon-containing compound has an ionization potential greater than 5.5 eV. This improves adhesiveness between the organic layer and the second electrode, and enhances an electric field to be substantially applied to the photoelectric conversion layer, thus making it possible to improve the manufacturing yield and the element characteristics.

(1)

An imaging element including:
a first electrode;
a second electrode disposed to be opposed to the first electrode;
an organic layer provided between the first electrode and the second electrode and at least including a photoelectric conversion layer; and
a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 eV or an electron affinity greater than a work function of the second electrode, the second carbon-containing compound having an ionization potential greater than 5.5 eV.
   (2)

The imaging element according to (1), in which the first semiconductor layer includes a mixed film in which at least the first carbon-containing compound and the second carbon-containing compound are mixed.

(3)

The imaging element according to (2), in which the mixed film has an electron affinity of 4.5 eV or more and 6.0 eV or less.

(4)

The imaging element according to (2) or (3), in which the mixed film has an electron affinity greater than the work function of the second electrode.

(5)

The imaging element according to any one of (1) to (4), in which a mixing ratio between the first carbon-containing compound and the second carbon-containing compound constituting the first semiconductor layer is 0.1 or more and 10 or less.

(6)

The imaging element according to any one of (1) to (5), in which the second carbon-containing compound includes a fullerene derivative.

(7)

The imaging element according to any one of (1) to (6), in which the first semiconductor layer has a crystalline grain size of 10 nm or less.

(8)

The imaging element according to any one of (1) to (7), in which the first semiconductor layer has an arithmetic mean roughness of 0.8 nm or less.

(9)

The imaging element according to any one of (1) to (8), in which an adhesive force between the first electrode and the second electrode is 0.05 KN/m or more.

(10)

The imaging element according to any one of (1) to (9), further including a second semiconductor layer provided between the second electrode and the first semiconductor layer, in which
an absolute value B of a difference between an ionization potential of the second semiconductor layer and a Fermi level of the second electrode is equal to or more than an absolute value A of a difference between an electron affinity of the second semiconductor layer calculated from an optical band gap and the Fermi level of the second electrode.
   (11)

The imaging element according to any one of (1) to (9), further including a second semiconductor layer provided between the second electrode and the first semiconductor layer, in which
the second semiconductor layer has, near a Fermi level of the second electrode, an in-gap level with a state density of 1/10000 or more with respect to a state density of an ionization potential of the second semiconductor layer.
   (12)

The imaging element according to any one of (1) to (11), in which the first electrode includes a plurality of electrodes independent of each other.

(13)

The imaging element according to (12), in which the first electrode includes a charge readout electrode and a charge accumulation electrode as the plurality of electrodes.

(14)

The imaging element according to (13), in which voltages are individually applied to the plurality of respective electrodes.

(15)

The imaging element according to (13) or (14), further including:
a third semiconductor layer between the first electrode and the organic layer, the third semiconductor layer including an oxide semiconductor material; and
an insulating layer between the first electrode and the third semiconductor layer, in which
the charge readout electrode is electrically coupled to the third semiconductor layer via an opening provided in the insulating layer.
   (16)

The imaging element according to any one of (1) to (15), in which the first electrode is disposed on the organic layer on a side opposite to a light incident surface.

(17)

The imaging element according to any one of (1) to (16), in which an organic photoelectric conversion section and one or a plurality of inorganic photoelectric conversion sections are stacked, the organic photoelectric conversion section including one or a plurality of the organic layers, the one or the plurality of inorganic photoelectric conversion sections each performing photoelectric conversion in a wavelength range different from the organic photoelectric conversion section.

(18)

The imaging element according to (17), in which
the inorganic photoelectric conversion section is formed to be embedded in a semiconductor substrate, and
the organic photoelectric conversion section is formed on a side of a first surface of the semiconductor substrate.
   (19)

The imaging element according to (18), in which
the organic photoelectric conversion section photoelectrically converts green light, and
an inorganic photoelectric conversion section photoelectrically converting blue light and an inorganic photoelectric conversion section photoelectrically converting red light are stacked inside the semiconductor substrate.
   (20)

An imaging device including a plurality of pixels each being provided with one or a plurality of imaging elements, the imaging elements each including
a first electrode,
a second electrode disposed to be opposed to the first electrode,
an organic layer provided between the first electrode and the second electrode and at least including a photoelectric conversion layer, and
a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 eV or an electron affinity greater than a work function of the second electrode, the second carbon-containing compound having an ionization potential greater than 5.5 eV.

This application claims the benefit of Japanese Priority Patent Application JP2021-123630 filed with the Japan Patent Office on Jul. 28, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising:
a first electrode;
a second electrode disposed to be opposed to the first electrode;
an organic layer provided between the first electrode and the second electrode and at least including a photoelectric conversion layer; and
a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 eV or an electron affinity greater than a work function of the second electrode, the second carbon-containing compound having an ionization potential greater than 5.5 eV.

2. The imaging element according to claim 1, wherein the first semiconductor layer comprises a mixed film in which at least the first carbon-containing compound and the second carbon-containing compound are mixed.

3. The imaging element according to claim 2, wherein the mixed film has an electron affinity of 4.5 eV or more and 6.0 eV or less.

4. The imaging element according to claim 2, wherein the mixed film has an electron affinity greater than the work function of the second electrode.

5. The imaging element according to claim 1, wherein a mixing ratio between the first carbon-containing compound and the second carbon-containing compound constituting the first semiconductor layer is 0.1 or more and 10 or less.

6. The imaging element according to claim 1, wherein the second carbon-containing compound comprises a fullerene derivative.

7. The imaging element according to claim 1, wherein the first semiconductor layer has a crystalline grain size of 10 nm or less.

8. The imaging element according to claim 1, wherein the first semiconductor layer has an arithmetic mean roughness of 0.8 nm or less.

9. The imaging element according to claim 1, wherein an adhesive force between the first electrode and the second electrode is 0.05 KN/m or more.

10. The imaging element according to claim 1, further comprising a second semiconductor layer provided between the second electrode and the first semiconductor layer, wherein an absolute value B of a difference between an ionization potential of the second semiconductor layer and a Fermi level of the second electrode is equal to or more than an absolute value A of a difference between an electron affinity of the second semiconductor layer calculated from an optical band gap and the Fermi level of the second electrode.

11. The imaging element according to claim 1, further comprising a second semiconductor layer provided between the second electrode and the first semiconductor layer, wherein the second semiconductor layer has, near a Fermi level of the second electrode, an in-gap level with a state density of 1/10000 or more with respect to a state density of an ionization potential of the second semiconductor layer.

12. The imaging element according to claim 1, wherein the first electrode includes a plurality of electrodes independent of each other.

13. The imaging element according to claim 12, wherein the first electrode includes a charge readout electrode and a charge accumulation electrode as the plurality of electrodes.

14. The imaging element according to claim 13, wherein voltages are individually applied to the plurality of respective electrodes.

15. The imaging element according to claim 13, further comprising:
a third semiconductor layer between the first electrode and the organic layer, the third semiconductor layer including an oxide semiconductor material; and
an insulating layer between the first electrode and the third semiconductor layer, wherein
the charge readout electrode is electrically coupled to the third semiconductor layer via an opening provided in the insulating layer.

16. The imaging element according to claim 1, wherein the first electrode is disposed on the organic layer on a side opposite to a light incident surface.

17. The imaging element according to claim 1, wherein an organic photoelectric conversion section and one or a plurality of inorganic photoelectric conversion sections are stacked, the organic photoelectric conversion section including one or a plurality of the organic layers, the one or the plurality of inorganic photoelectric conversion sections each performing photoelectric conversion in a wavelength range different from the organic photoelectric conversion section.

18. The imaging element according to claim 17, wherein
the inorganic photoelectric conversion section is formed to be embedded in a semiconductor substrate, and
the organic photoelectric conversion section is formed on a side of a first surface of the semiconductor substrate.

19. The imaging element according to claim 18, wherein
the organic photoelectric conversion section photoelectrically converts green light, and
an inorganic photoelectric conversion section photoelectrically converting blue light and an inorganic photoelectric conversion section photoelectrically converting red light are stacked inside the semiconductor substrate.

20. An imaging device comprising a plurality of pixels each being provided with one or a plurality of imaging elements, the imaging elements each including
a first electrode,
a second electrode disposed to be opposed to the first electrode,
an organic layer provided between the first electrode and the second electrode and at least including a photoelectric conversion layer, and
a first semiconductor layer provided between the second electrode and the organic layer and having an electron affinity of 4.5 eV or more and 6.0 eV or less, the first semiconductor layer including a first carbon-containing compound and a second carbon-containing compound, the first carbon-containing compound having an electron affinity greater than 4.8 e V or an electron affinity greater than a work function of the second electrode, the second carbon-containing compound having an ionization potential greater than 5.5 eV.
